(19) United States
(12) Patent Application Publication
(10) Pub. No.: US 2025/0160125 A1
(43) Pub. Date: May 15, 2025

(54) DISPLAY DEVICE AND METHOD OF FABRICATING THE SAME

(71) Applicant: c/o Samsung Display Co., LTD., Yongin-si (KR)

(72) Inventors: Jong Hwan CHA, Yongin-si (KR); Ki Nyeng KANG, Yongin-si (KR)

(21) Appl. No.: 18/731,054

(22) Filed: May 31, 2024

(30) Foreign Application Priority Data
Nov. 15, 2023 (KR) 10-2023-0157798

(51) Int. Cl. H10K 59/122; H10K 59/12

(52) U.S. Cl. CPC H10K 59/122; H10K 59/1201

(57) ABSTRACT

A display device includes a substrate including an emission area and a non-emission area, a first anode electrode at the emission area, a first cathode electrode above the first anode electrode, a first pixel-defining layer at the non-emission area, and defining a first opening, a bank structure above the first pixel-defining layer, and including a second bank layer contacting the first cathode electrode, and a third bank layer including a second tip protruding toward the emission area from a side surface of the second bank layer, a second pixel-defining layer above the bank structure, defining a second opening, overlapping the second tip in a direction perpendicular to the substrate, and contacting the second tip, and a first encapsulation layer above the second pixel-defining layer.

### CROSS-REFERENCE TO RELATED APPLICATION

The present application claims priority to, and the benefit of, Korean Patent Application No. 10-2023-0157798, filed on Nov. 15, 2023, in the Korean Intellectual Property Office, the entire disclosure of which is incorporated herein by reference.

### BACKGROUND

### 1. Field

The present disclosure relates to a display device and a method of fabricating the same.

### 2. Description of the Related Art

As the information-oriented society evolves, various demands for display devices are ever increasing. For example, display devices are being employed by a variety of electronic devices, such as smart phones, digital cameras, laptop computers, navigation devices, and smart televisions. Display devices may be flat-panel display devices, such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

Recently, as various electronic devices have developed, the demand for high-resolution display devices is increasing. Because high-resolution display devices require high pixel density, the spacing between light-emitting elements in each emission area may be narrowed. Therefore, a high-resolution display device can be formed via a patterning process that forms individual pixels rather than a process using a fine metal mask.

### SUMMARY

Aspects of the present disclosure provide a display device including a bank structure, and a display device that can address arc faults occurring during the fabrication process.

It should be noted that aspects of the present disclosure are not limited to the above, and other aspects of the present disclosure will be apparent to those skilled in the art from the following descriptions.

According to one or more embodiments of the present disclosure, a display device includes a substrate including an emission area and a non-emission area, a first anode electrode at the emission area, a first cathode electrode above the first anode electrode, a first pixel-defining layer at the non-emission area, and defining a first opening, a bank structure above the first pixel-defining layer, and including a second bank layer contacting the first cathode electrode, and a third bank layer including a second tip protruding toward the emission area from a side surface of the second bank layer, a second pixel-defining layer above the bank structure, defining a second opening, overlapping the second tip in a direction perpendicular to the substrate, and contacting the second tip, and a first encapsulation layer above the second pixel-defining layer.

The display device may further include a first bank layer between the first pixel-defining layer and the second bank layer, contacting the first pixel-defining layer, and including a first tip protruding toward the emission area from the side surface of the second bank layer.

The second bank layer may have higher electrical conductivity than the first bank layer and the third bank layer.

The first cathode electrode may cover the first tip.

The first pixel-defining layer and the second pixel-defining layer may include different respective inorganic materials.

The display device may further include a residual pattern between the first anode electrode and the first pixel-defining layer in a direction perpendicular to the substrate, and overlapping the first tip and the second tip in the direction perpendicular to the substrate.

The first opening may be completely surrounded by the second opening in plan view.

The display device may further include a second anode electrode spaced apart from the first anode electrode with the first pixel-defining layer therebetween, and a second cathode electrode above the second anode electrode, contacting the second bank layer, and electrically connected to the first cathode electrode by the second bank layer.

The display device may further include a second encapsulation layer above the first encapsulation layer, and including an organic material, wherein the first encapsulation layer includes a first inorganic layer covering the first cathode electrode, and a second inorganic layer covering the second cathode electrode and separated from the first inorganic layer by the second encapsulation layer at the non-emission area.

The second pixel-defining layer may include a first surface facing the second encapsulation layer and including a first portion overlapping the first inorganic layer, a second portion overlapping the second inorganic layer, and a third portion contacting the second encapsulation layer between the first portion and the second portion.

The display device may further include a first electrode pattern above the second pixel-defining layer, spaced apart from the first cathode electrode, and including a same material as the first cathode electrode, and a second electrode pattern above the second pixel-defining layer, spaced apart from the second cathode electrode, and including a same material as the second cathode electrode.

The first electrode pattern and the second electrode pattern may be spaced apart from each other in a direction parallel to the substrate with the second encapsulation layer therebetween.

According to one or more embodiments of the present disclosure, a display device includes a substrate including an emission area and a non-emission area, an anode electrode at the emission area, a cathode electrode above the anode electrode, a first pixel-defining layer at the non-emission area and defining a first opening, a bank structure above the first pixel-defining layer, and including a first bank layer, a second bank layer, and a third bank layer stacked on one another in a direction perpendicular to the substrate, and a second pixel-defining layer above the bank structure, defining a second opening, and including a first layer contacting the third bank layer, and a second layer above the first layer and including a second tip protruding toward the emission area from a side surface of the first layer.

The second bank layer may be completely surrounded by the first bank layer and the third bank layer.

The cathode electrode may contact the third bank layer.

The first bank layer may include a first tip protruding toward the emission area from a side surface of the second bank layer and overlapping the second tip in a direction perpendicular to the substrate.

The first layer and the second layer may include different respective inorganic materials.

The first pixel-defining layer may include a third layer facing the substrate, and a fourth layer above the third layer and including a first tip protruding toward the emission area from a side surface of the third layer.

The first tip may be in the first opening.

According to one or more embodiments of the present disclosure, a method of fabricating a display device includes preparing a substrate including an emission area and a non-emission area, forming an anode electrode at the emission area, forming a sacrificial layer above the anode electrode, forming a first pixel-defining material layer completely covering the sacrificial layer and the substrate, forming a bank material layer completely covering the first pixel-defining material layer, forming a second pixel-defining material layer, forming a photoresist above the bank material layer, removing portions of the first pixel-defining material layer, the bank material layer, and the second pixel-defining material layer overlapping the anode electrode via an etching process to form a hole exposing the sacrificial layer, removing an inner sidewall of the hole via an etching process to expose the anode electrode, forming a first pixel-defining layer, a second pixel-defining layer, and a bank structure protected by the second pixel-defining layer from an etchant during the etching process, and including a stacked structure of a second bank layer, a first bank layer above the second bank layer and including a first tip protruding toward the emission area from a side surface of the second bank layer, and a third bank layer below the second bank layer and including a second tip protruding toward the emission area from a side surface of the second bank layer, forming an emissive layer and a cathode electrode above the anode electrode and the second pixel-defining layer, forming a first encapsulation layer above the cathode electrode, and removing the emissive layer, the cathode electrode, and the first encapsulation layer above the second pixel-defining layer, leaving portions of the emissive layer, the cathode electrode, and the first encapsulation layer at the emission area and at a periphery of the emission area.

According to one or more embodiments of the present disclosure, a display device may include a bank structure, and a pixel-defining layer on the bank structure, which may include different conductive materials. At least one of the bank structures and the pixel-defining layer includes tips protruding toward emission areas, so that the display device according to one or more embodiments of the present disclosure can form light-emitting elements spaced apart from one another in the emission areas without a fine metal mask. In addition, the pixel-defining layer according to one or more embodiments of the present disclosure can protect the bank structure, thereby addressing arc faults in the bank structure which may occur during the fabrication process.

It should be noted that aspects of the present disclosure are not limited to those described above and other aspects of the present disclosure will be apparent to those skilled in the art from the following descriptions.

### BRIEF DESCRIPTION OF THE DRAWINGS

The above and other aspects of the present disclosure will become more apparent by describing in detail embodiments thereof with reference to the attached drawings, in which:

FIG. 1 is a perspective view showing an electronic device according to one or more embodiments of the present disclosure.

FIG. 2 is a perspective view showing a display device included in an electronic device according to one or more embodiments of the present disclosure.

FIG. 3 is a schematic cross-sectional view of the display device of FIG. 2.

FIG. 4 is a plan view showing a layout of emission areas in the display area of FIG. 3.

FIG. 5 is a cross-sectional view of the display layer, taken along the line X1-X1′ of FIG. 4.

FIG. 6 is an enlarged cross-sectional view schematically showing the non-emission area located between the first emission area and the second emission area in FIG. 5.

FIG. 7 is an enlarged cross-sectional view of area P of FIG. 6.

FIG. 8 is a plan view showing a layout of emission areas in the display area of FIG. 3 according to one or more other embodiments.

FIG. 9 is a cross-sectional view of the display layer, taken along the line X3-X3′ of FIG. 8.

FIG. 10 is an enlarged cross-sectional view schematically showing the non-emission area located between the first emission area and the second emission area in FIG. 9.

FIG. 11 is an enlarged cross-sectional view of area Q of FIG. 10.

FIG. 12 is a cross-sectional view of the display layer, taken along the line X3-X3 of FIG. 8 according to one or more other embodiments.

FIG. 13 is an enlarged cross-sectional view schematically showing the non-emission area located between the first emission area and the second emission area in FIG. 12.

FIGS. 14 to 25 are schematic cross-sectional views showing a method of fabricating the display element layer shown in FIG. 5.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions, such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described with reference to the accompanying drawings.

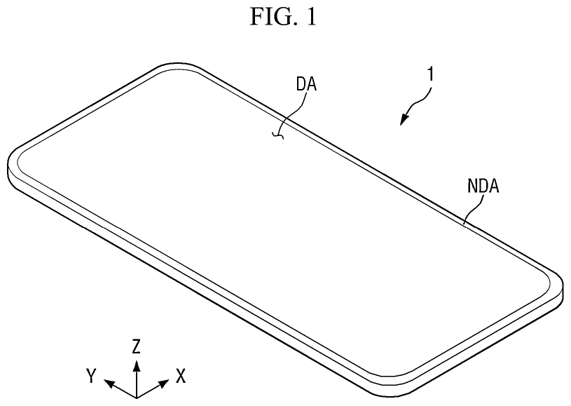

FIG. 1 is a perspective view showing an electronic device according to one or more embodiments of the present disclosure.

Referring to FIG. 1, an electronic device 1 displays a moving image or a still image. The electronic device 1 may refer to any electronic device that provides a display screen. For example, the electronic device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

In FIG. 1, a first direction (x-axis direction), a second direction (y-axis direction), and a third direction (z-axis direction) are defined. The first direction (x-axis direction) and the second direction (y-axis direction) may be perpendicular to each other, the first direction (x-axis direction) and the third direction (z-axis direction) may be perpendicular to each other, and the second direction (y-axis direction) and the third direction (z-axis direction) may be perpendicular to each other. The first direction (x-axis direction) may refer to the horizontal direction in the drawings (e.g., in plan view), the second direction (y-axis direction) may refer to the vertical direction in the drawings (in plan view), and the third direction (z-axis direction) may refer to the up-and-down direction (e.g., the thickness direction) in the drawings (e.g., in cross-sectional view). As used herein, a direction may refer to the direction indicated by the arrow, as well as the direction opposite thereto, unless specifically stated otherwise. If it is suitable to discern between such two opposite directions, one of the two directions may be referred to as “one side in the direction,” while the other direction may be referred to as “the opposite side in the direction.” In FIG. 1, the side indicated by an arrow indicative of a direction is referred to as one side in the direction, while the opposite side is referred to as the opposite side in the direction.

In the following description of the surfaces of the electronic device 1 or the elements of the electronic device 1, the surface facing one side where images are displayed (e.g., the side indicated by the arrow in the third direction (z-axis direction)) will be referred to as the upper surface, while the opposite surface will be referred to as the lower surface, for convenience of illustration. It should be understood, however, that the present disclosure is not limited thereto. The surfaces and the opposite surface of each of the elements may be referred to as a front surface and a rear surface, respectively, or may be referred to as a first surface and a second surface, respectively. In addition, in the description of relative positions of the elements of the electronic device 1, one side in the third direction (z-axis direction) may be referred to as the upper side, while the opposite side in the third direction (z-axis direction) may be referred to as the lower side.

The shape of the electronic device 1 may be modified in a variety of ways. For example, the electronic device 1 may have shapes, such as a rectangle with longer lateral sides, a rectangle with longer vertical sides, a square, a quadrangle with rounded corners (vertices), other polygons, a circle, etc.

The electronic device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electronic device 1.

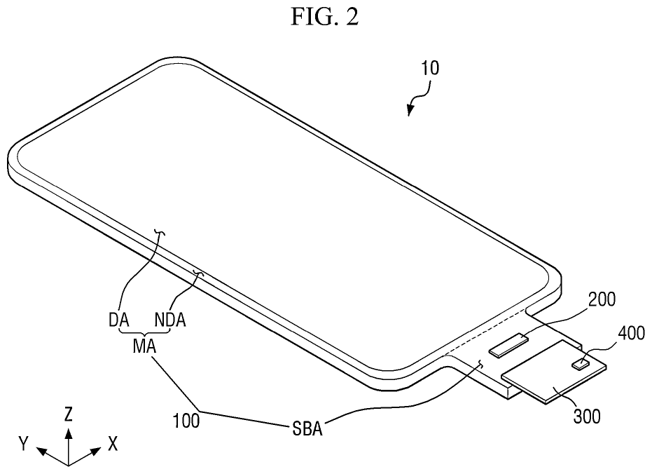

FIG. 2 is a perspective view showing a display device 10 included in the electronic device 1.

Referring to FIG. 2, the electronic device 1 may include the display device 10. The display device 10 may provide a display screen where images are displayed in the electronic device 1. Examples of the display device 10 may include an inorganic light-emitting diode display device, an organic light-emitting display device, a quantum-dot light-emitting display device, a plasma display device, a field emission display device, etc. In the following description, an organic light-emitting diode display device is employed as an example of the display device, but the present disclosure is not limited thereto. Any other display device may be employed as long as the technical idea of the present disclosure can be equally applied.

The display device 10 may have a shape similar to that of the electronic device 1 when viewed from the top. For example, the display device 10 may have a shape similar to a rectangle having shorter sides in the first direction (x-axis direction), and longer sides in the second direction (y-axis direction). The corners where the shorter sides in the first direction (x-axis direction) meet the longer sides in the second direction (y-axis direction) may be rounded with a curvature (e.g., a predetermined curvature). It should be understood, however, that the present disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300, and a touch driver 400.

The display panel 100 may include a main area MA and a subsidiary area SBA. The main area MA may include the display area DA including pixels for displaying images, and the non-display area NDA located around the display area DA.

The display area DA may emit light from a plurality of emission areas or a plurality of openings to be described later. For example, the display panel 100 may include pixel circuits including switching elements, a pixel-defining layer that defines the emission areas or the openings, and self-light-emitting elements. For example, the self-light-emitting element may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED). In the following drawings, it is illustrated that the self-luminous element is an organic light-emitting diode.

The non-display area NDA may be on the outer side of the display area DA (e.g., in plan view). The non-display area NDA may be defined as the edge of the main area MA of the display panel 100.

The subsidiary area SBA may extend from one side of the main area MA. The subsidiary area SUB may include a flexible material that can be bent, folded, or rolled. For example, when the subsidiary area SBA is bent, the subsidiary area SBA may overlap the main area MA in the thickness direction (e.g., the third direction or z-axis direction). The subsidiary area SBA may include pads connected to the display driver 200 and the circuit board 300. According to one or more other embodiments, the subsidiary area SBA may be eliminated, and the display driver 200 and the pads may be located in the non-display area NDA.

The display driver 200 may output signals and voltages for driving the display panel 100. The display driver 200 may be implemented as an integrated circuit (IC), and may be attached on the display panel 100 by a chip-on-glass (COG) technique, a chip-on-plastic (COP) technique, or ultrasonic bonding. For example, the display driver 200 may be located in the subsidiary area SBA, and may overlap with the main area MA in the thickness direction as the subsidiary area SBA is bent. For another example, the display driver 200 may be mounted on the circuit board 300.

The circuit board 300 may be attached on the pad area of the display panel 100 using an anisotropic conductive film (ACF). The circuit board 300 may be a flexible printed circuit board (FPCB), a printed circuit board (PCB), or a flexible film, such as a chip-on-film (COF).

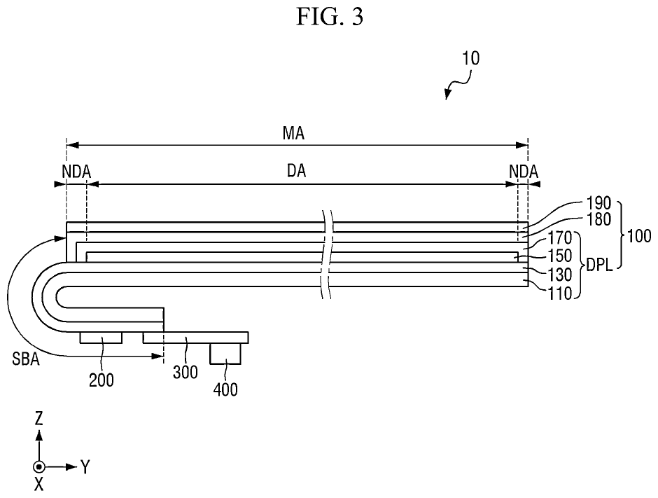

The touch driver 400 may be mounted on the circuit board 300. The touch driver 400 may be connected to a touch sensor layer 180 (see FIG. 3) of the display panel 100. The touch driver 400 may be implemented as an integrated circuit.

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin-film transistor layer 130, a display element layer 150, a thin-film encapsulation layer 170.

The substrate 110 may be a base substrate or a base member. The substrate 110 may be a flexible substrate that can be bent, folded, or rolled. For example, the substrate 110 may include, but is not limited to, a polymer resin, such as polyimide PI. According to one or more other embodiments, the substrate 110 may include a glass material or a metal material.

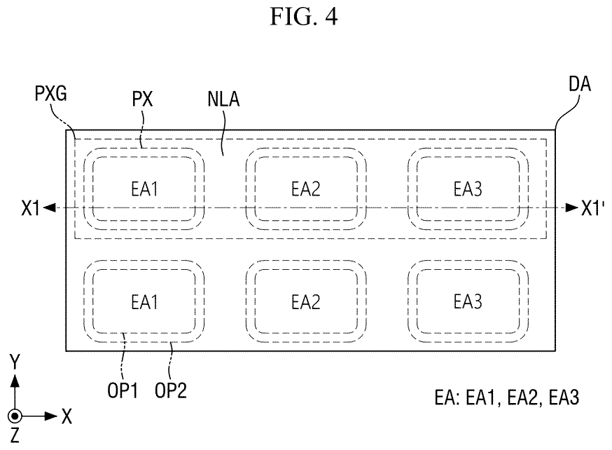

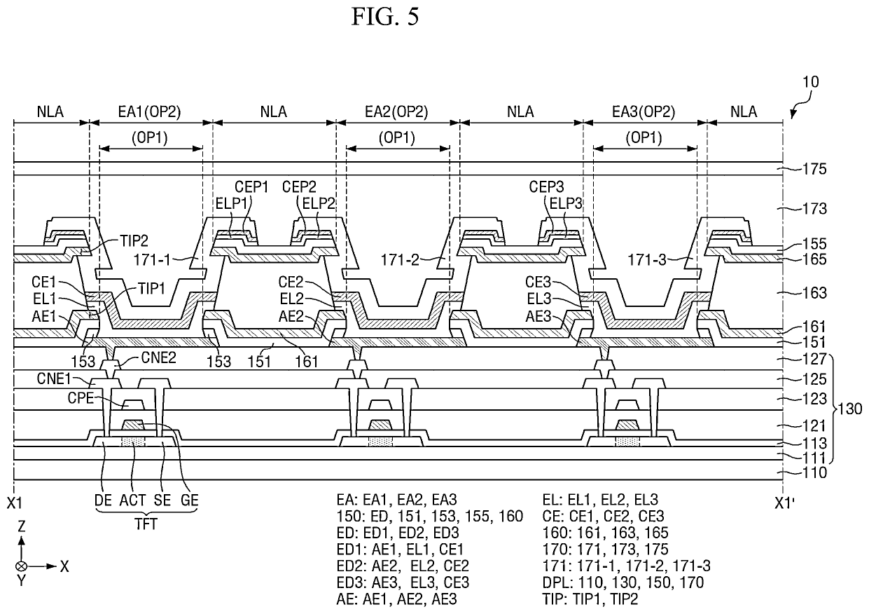

The thin-film transistor layer 130 may be located on the substrate 110. The thin-film transistor layer 130 may be located in the display area DA, the non-display area NDA, and the subsidiary area SBA. The thin-film transistor layer 130 may include a plurality of thin-film transistors TFT (see FIG. 5) for forming pixels PX (see FIG. 4).

The display element layer 150 may be located on the thin-film transistor layer 130. The display element layer 150 may be located in the display area DA. The display element layer 150 may include a plurality of light-emitting elements ED (see FIG. 5). For example, the self-light-emitting element may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED).

The thin-film encapsulation layer 170 may be located on the display element layer 150. The thin-film encapsulation layer 170 may overlap the display area DPA and the non-display area NDA. The thin-film encapsulation layer 170 may cover the upper and side surfaces of the display element layer 150, and can protect the display element layer 150 from outside oxygen and moisture. The thin-film encapsulation layer 170 may include at least one inorganic film and at least one organic film for encapsulating the display element layer 150.

The touch sensor layer 180 may be located on the thin-film encapsulation layer 170. The touch sensor layer 180 may overlap the display area DPA and the non-display area NDA. The touch sensor layer 180 may sense a user's touch by mutual capacitance sensing or self-capacitance sensing.

The color filter layer 190 may be located on the touch sensor layer 180. The color filter layer 190 may overlap the display area DPA and the non-display area NDA. The color filter layer 190 may absorb some of lights introduced from the outside of the display device 10 to reduce the reflection of external light. Accordingly, the color filter layer 190 can reduce or prevent distortion of colors due to the reflection of external light.

Because the color filter layer 190 is located directly on the touch sensor layer 180, the display device 10 may require no separate substrate for the color filter layer 190. Therefore, the thickness of the display device 10 can be relatively small. In addition, the color filter layer 190 may be eliminated in some implementations.

As shown in FIG. 3, a portion of the display layer DPL overlapping with the subsidiary area SBA may be bent. When a portion of the display layer DPL is bent, the display driver 200, the circuit board 300 and the touch driver 400 may overlap with the main area MA in the third direction (z-axis direction).

FIG. 4 is a plan view showing a layout of emission areas in the display area DA of FIG. 3.

Referring to FIG. 4, the display area DA may include the first to third emission areas EA1, EA2, and EA3 and a non-emission area NLA. The non-emission area NLA may surround the first to third emission areas EA1, EA2, and EA3.

The non-emission area NLA can block the lights exiting from the first to third emission areas EA1, EA2, and EA3. Accordingly, the non-emission area NLA can help reduce or prevent mixture of the lights exiting from the first to third emission areas EA1, EA2, and EA3. In the non-emission area NLA, a first pixel-defining layer 151 (see FIG. 5), a bank structure 160 (see FIG. 5), and a second pixel-defining layer 155 (see FIG. 5) may be arranged, which will be described later.

The emission areas EA may include first emission areas EA1, second emission areas EA2, and third emission areas EA3 that emit lights of different respective colors. Each of the first to third emission areas EA1, EA2, and EA3 may emit red, green, or blue light. The colors of lights emitted from the first to third emission areas EA1, EA2, and EA3 may vary depending on the type of light-emitting elements ED, which will be described later. According to one or more embodiments of the present disclosure, the first emission area EA1 may emit light of a first color (e.g., red light), the second emission area EA2 may emit light of a second color (e.g., green color), and the third emission area EA3 may emit light of a third color (e.g., blue color). It should be understood, however, that the present disclosure is not limited thereto. Although the first to third emission areas EA1, EA2, and EA3 have the same size and shape in the drawings, the present disclosure is not limited thereto. The size and shape of the first to third emission areas EA1, EA2, and EA3 may be adjusted as desired according to required characteristics.

The first to third emission areas EA1, EA2, and EA3 may be defined by first openings OP1 and second openings OP2. For example, and referring to FIG. 5, the first openings OP1 may be defined by the first pixel-defining layer 151, and the second openings OP2 may be defined by the second pixel-defining layer 155. The second openings OP2 may completely surround the first openings OP1 when viewed from the top. The second openings OP2 may be completely surrounded by the non-emission area NLA when viewed from the top.

According to some embodiments, at least one first emission area EA1, at least one second emission areas EA2, and at least one third emission area EA3 arranged adjacent to each other may form a single pixel group PXG. A pixel group PXG may be the minimum unit that emits white light. However, the type and/or number of each of the first to third emission areas EA1, EA2, and EA3 forming a pixel group PXG may vary depending on embodiments.

FIG. 5 is a cross-sectional view of the display layer DPL, taken along the line X1-X1′ of FIG. 4. FIG. 5 shows a schematic cross section of the display layer DPL in the display area DA. For example, FIG. 5 shows the cross section of the substrate 110, the thin-film transistor layer 130, the display element layer 150 and the thin-film encapsulation layer 170 of the display device 10. The substrate 110 has been described above, and thus will not be described again.

Referring to FIG. 5, the thin-film transistor layer 130 may be located on the substrate 110. The thin-film transistor layer 130 may include a first buffer layer 111, a thin-film transistor TFT, a gate insulator 113, a first interlayer dielectric layer 121, a capacitor electrode CPE, a second interlayer dielectric layer 123, a first connection electrode CNE1, a first via layer 125, a second connection electrode CNE2, and a second via layer 127.

The first buffer layer 111 may be located on the substrate 110. The first buffer layer 111 may include an inorganic film capable of reducing or preventing permeation of air or moisture. For example, the first buffer layer 111 may include a plurality of inorganic films stacked on one another alternately.

The thin-film transistor TFT may be located on the first buffer layer 111, and may form, or may be part of, a pixel circuit connected to each of a plurality of pixels. For example, the thin-film transistor TFT may be a driving transistor or a switching transistor of the pixel circuit. The thin-film transistor TFT may include an active layer ACT, a source electrode SE, a drain electrode DE, and a gate electrode GE.

The active layer ACT may be located on the first buffer layer 111. The active layer ACT may overlap with the gate electrode GE in the third direction (z-axis direction), and may be insulated from the gate electrode GE by the gate insulator 113. The material of a part of the active layer ACT may be made conductive to form the source electrode SE and the drain electrode DE.

The gate electrode GE may be located on the gate insulator 113. The gate electrode GE may overlap the active layer ACT, with the gate insulator 113 interposed therebetween.

The gate insulator 113 may be located over the active layer ACT. The gate insulator 131 may cover the active layer ACT and the first buffer layer 111, and may insulate the active layer ACT from the gate electrode GE. The gate insulator 113 may define a contact hole through which the first connection electrode CNE1 passes.

The first interlayer dielectric layer 121 may cover the gate electrode GE and the gate insulator 113. The first interlayer dielectric layer 121 may define a contact hole through which the first connection electrode CNE1 passes. The contact hole of the first interlayer dielectric layer 121 may be connected to the contact hole of the gate insulating layer 113 and to a contact hole of the second interlayer dielectric layer 123.

The capacitor electrode CPE may be located on the first interlayer dielectric layer 121. The capacitor electrode CPE may overlap with the gate electrode GE in the third direction (z-axis direction). The capacitor electrode CPE and the gate electrode GE may form a capacitance.

The second interlayer dielectric layer 123 may cover the capacitor electrode CPE and the first interlayer dielectric layer 121. The second interlayer dielectric layer 123 may define a contact hole through which the first connection electrode CNE1 passes. The contact hole of the second interlayer dielectric layer 123 may be connected to the contact hole of the first interlayer dielectric layer 121 and to the contact hole of the gate insulating layer 113.

The first connection electrode CNE1 may be located on the second interlayer dielectric layer 123. The first connection electrode CNE1 may electrically connect the drain electrode DE of the thin-film transistor TFT with the second connection electrode CNE2. The first connection electrode CNE1 may be inserted into a contact hole formed in the first interlayer dielectric layer 121, the second interlayer dielectric layer 123, and the gate insulator 113 to contact the drain electrode DE of the thin-film transistor TFT.

The first via layer 125 may cover the first connection electrode CNE1 and the second interlayer dielectric layer 123. The first via layer 125 may provide a flat surface over the underlying structures. The first via layer 125 may define a contact hole through which the second connection electrode CNE2 passes.

The second connection electrode CNE2 may be located on the first via layer 125. The second connection electrode CNE2 may be inserted into a contact hole formed in the first via layer 125 to contact the first connection electrode CNE1. The second connection electrode CNE2 may electrically connect the first connection electrode CNE1 with an anode electrode AE.

The second via layer 127 may cover the second connection electrode CNE2 and the first via layer 125. The second via layer 127 may define a contact hole through which the anode electrode AE passes.

The display element layer 150 may be located on the second via layer 127. The display element layer 150 may include light-emitting elements ED, a first pixel-defining layer 151, residual patterns 153, a second pixel-defining layer 155, and a bank structure 160.

The light-emitting element ED may include the anode electrode AE, an emissive layer EL, and a common electrode CE. The light-emitting elements ED may include a first light-emitting element ED1 located in the first emission area EA1, a second light-emitting element ED2 located in the second emission area EA2, and a third light-emitting element ED3 located in the third emission area EA3.

The light-emitting elements ED overlapping with the respective emission areas EA1, EA2, and EA3 may emit lights of different respective colors depending on the materials of the emissive layers EL. For example, the first light-emitting element ED1 may emit light of the first color (e.g., red light), the second light-emitting element ED2 may emit light of the second color (e.g., green light), and the third light-emitting element ED3 may emit light of the third color (e.g., blue light).

The anode electrode AE may be located on the second via layer 127. The anode electrode AE may be electrically connected to the drain electrode DE of the thin-film transistor TFT through the first connection electrode CNE1 and the second connection electrode CNE2.

The anode electrodes AE may include a first anode electrode AE1 located in the first emission area EA1, a second anode electrode AE2 located in the second emission area EA2, and a third anode electrode AE3 located in the third emission area EA3. The first anode electrode AE1, the second anode electrode AE2, and the third anode electrode AE3 may be spaced apart from one another on the second via layer 127.

According to one or more embodiments of the present disclosure, the anode electrodes AE may have a stack structure of a material layer having a high work function, such as indium-tin-oxide (ITO), indium-zinc-oxide (IZO), zinc oxide (ZnO), or indium oxide (In₂O₃), and a reflective material layer, such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or a mixture thereof. For example, the anode electrodes AE may have, but is not limited to, a multilayer structure of ITO/Mg, ITO/MgF, ITO/Ag, or ITO/Ag/ITO.

The first pixel-defining layer 151 may be located on the second via layer 127 and the anode electrode AE. The first pixel-defining layer 151 may separate and insulate the first to third anode electrodes AE1, AE2, and AE3 from one another. The first pixel-defining layer 151 may define the first openings OP1. The first pixel-defining layer 151 may be located entirely on the second via layer 127, and may expose parts of the upper surfaces of the anode electrodes AE1. In other words, the first pixel-defining layer 151 may expose the anode electrodes AE in the first openings OP1, and the emissive layers EL may be located directly on the anode electrodes AE in the first openings OP1.

The first pixel-defining layer 151 may include an inorganic insulating material. For example, the first pixel-defining layer 151 may include silicon oxide, silicon nitride, or silicon oxynitride.

The bank structure 160 may be located on the first pixel-defining layer 151. The bank structure 160 may be located in the non-emission area NLA. The bank structure 160 may include a first bank layer 161, a second bank layer 163, and a third bank layer 165 located on the first pixel-defining layer 151. The bank structure 160 may have a structure in which a first bank layer 161, a second bank layer 163, and a third bank layer 165 are sequentially stacked.

The first bank layer 161 may include first tips TIP1 that protrude toward the emission area EA from the second bank layer 163. In addition, the third bank layer 165 may include second tips TIP2 that protrude toward the emission area EA from the second bank layer 163.

In the display device 10, as the bank structure 160 includes the tips TIP, the first to third light-emitting elements ED1, ED2, and ED3 may be formed in the first to third emission areas EA1, EA2, and EA3, respectively, even without a fine metal mask during the process of fabricating the display device 10. The fabrication process will be described below.

The second pixel-defining layer 155 may be located on the bank structure 160. The second pixel-defining layer 155 may help reduce or prevent exposure of the bank structure 160 to an etchant during an etching process in the process of fabricating the display device 10.

The second pixel-defining layer 155 may define the second openings OP2. The first to third emission areas EA1, EA2, and EA3 may be defined by the second openings OP2.

The second pixel-defining layer 155 may include an inorganic insulating material. For example, the second pixel-defining layer 155 may include silicon oxide, silicon nitride, and silicon oxynitride. According to one or more embodiments of the present disclosure, the second pixel-defining layer 155 may have a different material from the first pixel-defining layer 151. For example, if the first pixel-defining layer 151 includes silicon oxide, the second pixel-defining layer 155 may include silicon nitride and/or silicon oxynitride excluding silicon oxide. This may utilize different etch ratios of the first pixel-defining layer 151 and the second pixel-defining layer 155 in the process of fabricating the first pixel-defining layer 151 and the second pixel-defining layer 155. The fabrication process will be described later.

The emissive layers EL may be located on the anode electrodes AE. The emissive layers EL may be organic emissive layers made of an organic material, and may be formed on the anode electrodes AE via a deposition process. If the thin-film transistor TFT applies a voltage (e.g., a predetermined voltage) to the anode electrode AE, and if the cathode electrode CE receives a common voltage or cathode voltage, the holes and electrons may move to the emissive layer EL through a hole-transporting layer and an electron-transporting layer, respectively, and they combine in the emissive layer EL to emit light.

The emissive layers EL may include a first emissive layer EL1, a second emissive layer EL2, and a third emissive layer EL3 located in the first to third emission areas EA1, EA2, and EA3, respectively. For example, the first emissive layer EL1 may emit red light of the first color, the second emissive layer EL2 may emit green light of the second color, and the third emissive layer EL3 may emit blue light of the third color. It should be understood, however, that the present disclosure is not limited thereto.

According to some embodiments, the anode electrodes AE and the first pixel-defining layer 151 may be spaced apart from each other in the third direction (z-axis direction). Residual patterns 153 may be located where the anode electrodes AE and the first pixel-defining layer 151 are spaced apart from each other. The residual patterns 153 will be described later.

The cathode electrode CE may be located on the emissive layer EL. The cathode electrode CE may include a transparent conductive material so that light generated in the emissive layer EL can exit. The cathode electrode CE may receive a common voltage or a low-level voltage. When the anode electrode AE receives the voltage equal to the data voltage and the cathode electrode CE receives the low-level voltage, a potential difference is formed between the anode electrode AE and the cathode electrode CE, so that the emissive layer EL can emit light.

According to one or more embodiments of the present disclosure, the cathode electrode CE may include a material layer having a small work function, such as Li, Ca, LiF/Ca, LiF/Al, Al, Mg, Ag, Pt, Pd, Ni, Au, Nd, Ir, Cr, BaF, or Ba, or a compound or mixture thereof (e.g., a mixture of Ag and Mg). The cathode electrode CE may further include a transparent metal oxide layer located on the material layer having a small work function.

The cathode electrodes CE may include a first cathode electrode CE1, a second cathode electrode CE2, and a third cathode electrode CE3 located in the first to third emission areas EA1, EA2, and EA3, respectively. The first cathode electrode CE1 may be located on the first emissive layer EL1 in the first emission area EA1, the second cathode electrode CE2 may be located on the second emissive layer EL2 in the second emission area EA2, and the third cathode electrode CE3 may be located on the third emissive layer EL3 in the third emission area EA3.

The cathode electrodes CE may be located in the first to third emission areas EA1, EA2, and EA3, respectively, such that they are spaced apart from one another. The cathode electrodes CE may not be directly connected with one another, but may be electrically connected with one another through the second bank layer 163.

A plurality of first to third organic patterns ELP1, ELP2, and ELP3 and first to third electrode patterns CEP1, CEP2, and CEP3 may be located on the second pixel-defining layer 155. A plurality of first to third organic patterns ELP1, ELP2, and ELP3 and the first to third electrode patterns CEP1, CEP2, and CEP3 may be located to surround the first openings OP1.

The first to third organic patterns ELP1, ELP2, and ELP3 may be located on the second pixel-defining layer 155 in contact therewith. The first to third organic patterns ELP1, ELP2, and ELP3 may include the same materials as the first to third emission layers EL1, EL2, and EL3, respectively. For example, the first organic pattern ELP1 may include the same material as the first emissive layer EL1, the second organic pattern ELP2 may include the same material as the second emissive layer EL2, and the third organic pattern ELP2 may include the same material as the third emissive layer ELP3. The first to third organic patterns ELP1, ELP2, and ELP3 may be traces that are formed as they are disconnected from the first to third emissive layers EL1, EL2, and EL3 because the bank structure 160 includes the tips TIP.

The first to third electrode patterns CEP1, CEP2, and CEP3 may be located on the first to third organic patterns ELP1, ELP2, and ELP3, respectively. For example, the first electrode pattern CEP1, the second electrode pattern CEP2, and the third electrode pattern CEP3 may be located directly on the first organic pattern ELP1, the second organic pattern ELP2, and the third organic pattern ELP3, respectively. The arrangement relationship between the first to third electrode patterns CEP1, CEP2, and CEP3 and the first to third organic patterns ELP1, ELP2, and ELP3 may be identical to the arrangement relationship between the first to third emissive layers EL1, EL2, and EL3 and the first to third cathode electrodes CE1, CE2, and CE3. The first to third electrode patterns CEP1, CEP2, and CEP3 may include the same materials as the first to third cathode electrodes CE1, CE2, and CE3, respectively. The first to third electrode patterns CEP1, CEP2, and CEP3 may be traces that are formed as they are disconnected from the first to third cathode electrodes CE1, CE2, and CE3 because the bank structure 160 includes the tips TIP.

The thin-film encapsulation layer 170 may be located on the first to third cathode electrodes CE1, CE2, and CE3 and the first to third electrode patterns CEP1, CEP2, and CEP3. The thin-film encapsulation layer 170 may contact the first to third cathode electrodes CE1, CE2, and CE3 and the first to third electrode patterns CEP1, CEP2, and CEP3.

The thin-film encapsulation layer 170 may include a first encapsulation layer 171, a second encapsulation layer 173, and a third encapsulation layer 175 sequentially stacked on one another. The first encapsulation layer 171 and the third encapsulation layer 175 may be inorganic encapsulation layers, and the second encapsulation layer 173 located therebetween may be an organic encapsulation layer.

Each of the first encapsulation layer 171 and the third encapsulation layer 175 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), or silicon oxynitride (Si₂N₂O).

The second encapsulation layer 173 may include a polymer-based material. The polymer-based material may include an acrylic resin, an epoxy resin, polyimide, polyethylene, etc. For example, the second encapsulation layer 173 may include an acrylic resin, e.g., polymethyl methacrylate, polyacrylic acid, etc. The second encapsulation layer 173 may be formed by curing a monomer or by applying a polymer.

The first encapsulation layer 171 may include first to third inorganic layers 171-1, 171-2, and 171-3. The first to third inorganic layers 171-1, 171-2, and 171-3 may overlap with the emission areas EA1, EA2, and EA3, respectively. For example, the first inorganic layer 171-1 may be located in the first emission area EA1 and may cover the first light-emitting element ED1. In addition, the second inorganic layer 171-2 may be located in the second emission area EA2 and may cover the second light-emitting element ED2. Further, the third inorganic layer 171-3 may be located in the third emission area EA3 and may cover the third light-emitting element ED3.

Although the first to third inorganic layers 171-1, 171-2, and 171-3 are formed in the same layer in the drawings, the first to third inorganic layers 171-1, 171-2, and 171-3 may be formed in different processes. For example, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The fabrication process will be described below.

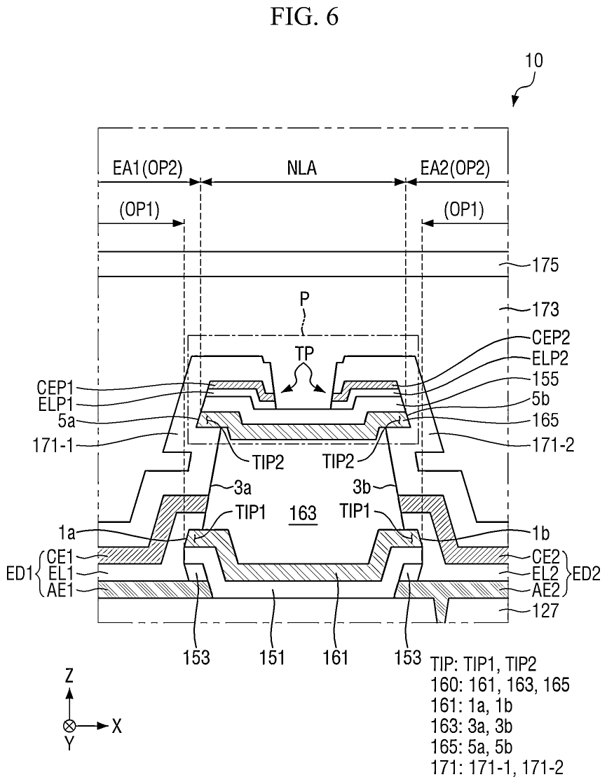

FIG. 6 is an enlarged cross-sectional view schematically showing the non-emission area NLA located between the first emission area EA1 and the second emission area EA2 in FIG. 5.

According to the one or more embodiments corresponding to FIG. 6, the first emission area EA1 and the second emission area EA2 may be spaced apart from each other with the non-emission area NLA therebetween. As described above, the first openings OP1 may be defined by the first pixel-defining layer 151, and the second openings OP2 may be defined by the second pixel-defining layer 155.

The first bank layer 161 may be located on the first pixel-defining layer 151. The first bank layer 161 may include a metal material that has high electrical stability and suitable adhesion with metal, and may be, for example, molybdenum (Mo). It should be understood, however, that the present disclosure is not limited thereto. The first bank layer 161 may include one of chromium (Cr), gold (Au), titanium (Ti), nickel (Ni), or neodymium (Nd), or an alloy thereof, in addition to molybdenum (Mo).

According to some embodiments, the first bank layer 161 may include a first side surface 1a facing the first emission area EA1, and a second side surface 1b facing the second emission area EA2. The first side surface 1a of the first bank layer 161 may protrude from (e.g., may protrude beyond, or further than) the second bank layer 163 toward the first emission area EA1, and the second side surface 1b of the first bank layer 161 may protrude from the second bank layer 163 toward the second emission area EA2.

During the process of fabricating the display device 10, the first bank layer 161 may include a metal material that is relatively stable compared to the second bank layer 163 in an etching process. In other words, according to one or more embodiments of the present disclosure, the etch rate of the first bank layer 161 may be less than the etch rate of the second bank layer 163. Therefore, the first side surface a and the second side surface 1b of the first bank layer 161 may respectively protrude beyond both sides from the second bank layer 163. In other words, the first bank layer 161 may include first tips TIP1 that protrude from the second bank layer 163 in the first direction (x-axis direction) toward the first and second emission areas EA1 and EA2.

In the display device 10 as the first bank layer 161 includes the first tips TIP1, the first to third light-emitting elements ED1, ED2, and ED3 can be formed without a fine metal mask during the process of fabricating the display device 10. In addition, in the display device 10 as the first bank layer 161 includes the first tips TIP1, the first to third emissive layers EL1, EL2, and EL3 and the first to third cathode electrodes CE1, CE2, and CE3 can be connected without being disconnected.

The second bank layer 163 may contact the first bank layer 161. The second bank layer 163 may include a material with suitable electrical conductivity, and accordingly can electrically connect between the first to third cathode electrodes CE1, CE2, and CE3 located separately in the first to third emission areas EA1, EA2, and EA3, respectively. For example, the second bank layer 163 may include at least one of aluminum (Al) or copper (Cu).

According to some embodiments, the second bank layer 163 may include a first side 3a facing the first emission area EA1, and a second side surface 3b facing the second emission area EA2. The first side surface 3a of the second bank layer 163 may be recessed from (e.g., recessed further than) the first side surface 1a of the first bank layer 161 in the first direction (x-axis direction), and the second side surface 3b of the second bank layer 163 may be recessed from the second side surface 1b of the first bank layer 161 in the opposite direction to the first direction (x-axis direction). This may be because the second bank layer 163 includes a material with a relatively high etch rate compared to the first bank layer 161 and the third bank layer 165.

The first emissive layer EL1, the first cathode electrode CE1 and the first inorganic layer 171-1 may contact the first side surface 3a of the second bank layer 163. The second emissive layer EL2, the second cathode electrode CE2 and the second inorganic layer 171-2 may contact the second side surface 3b of the second bank layer 163. As described above, the first cathode electrode CE1 and the second cathode electrode CE2 may be electrically connected with each other through the second bank layer 163.

The third bank layer 165 may contact the second bank layer 163. The third bank layer 165 may include a metal material that has high electrical stability and suitable adhesion with metal, and may be, for example, molybdenum (Mo). It should be understood, however, that the present disclosure is not limited thereto. The third bank layer 165 may include one of chromium (Cr), gold (Au), titanium (Ti), nickel (Ni), or neodymium (Nd), or an alloy thereof, in addition to molybdenum (Mo).

According to some embodiments, the third bank layer 165 may include a first side surface 5a facing the first emission area EA1, and a second side surface 5b facing the second emission area EA2. The first side surface 5a of the third bank layer 165 may protrude from the first side surface 3a of the second bank layer 163 toward the first emission area EA1, and the second side surface 5b of the third bank layer 165 may protrude from the second side surface 3b of the second bank layer 163 toward the second emission area EA2.

During the process of fabricating the display device 10, the third bank layer 165 may include a metal material that is relatively stable compared to the second bank layer 163 in an etching process. In other words, the etch rate of the third bank layer 165 may be lower than the etch rate of the second bank layer 163. Therefore, the first side surface 5a and the second side surface 5b of the third bank layer 165 may protrude from the second bank layer 163 toward the emission area EA. In other words, the third bank layer 165 may include second tips TIP2 that respectively protrude from the second bank layer 163 on both sides toward the first and second emission areas EA1 and EA2. For example, undercuts may be formed between the first side surface 3a of the second bank layer 163 and the second tip TIP2, and between the second side surface 3b of the second bank layer 163 and the second tip TIP2.

In the display device 10 as the third bank layer 165 includes the second tips TIP2, the first to third light-emitting elements ED1, ED2, and ED3 can be formed without a fine metal mask during the process of fabricating the display device 10. That is to say, the first to third light-emitting elements ED1, ED2, and ED3 can be formed in the display device 10 via deposition and photo processes without a fine metal mask.

In addition, in the display device 10, as the third bank layer 165 includes the second tips TIP2, the first emissive layer EL1 and the first organic pattern ELP1 may be spaced apart from each other, and the first cathode electrode CE1 and the first electrode pattern CEP1 may be spaced apart from each other. In addition, in the display device 10, as the third bank layer 165 includes the second tips TIP2, the second emissive layer EL2 and the second organic pattern ELP2 may be spaced apart from each other, and the second cathode electrode CE2 and the second electrode pattern CEP2 may be spaced apart from each other.

The second pixel-defining layer 155 may contact the third bank layer 165. The second pixel-defining layer 155 will be described later.

The residual pattern 153 may be located between the first anode electrode AE1 and the first pixel-defining layer 151 in the third direction (z-axis direction), and may be located between the second anode electrode AE2 and the first pixel-defining layer 151 in the third direction (z-axis direction). In addition, the residual patterns 153 may overlap with the protruding tips TIP of the bank structure 160 in the third direction (z-axis direction).

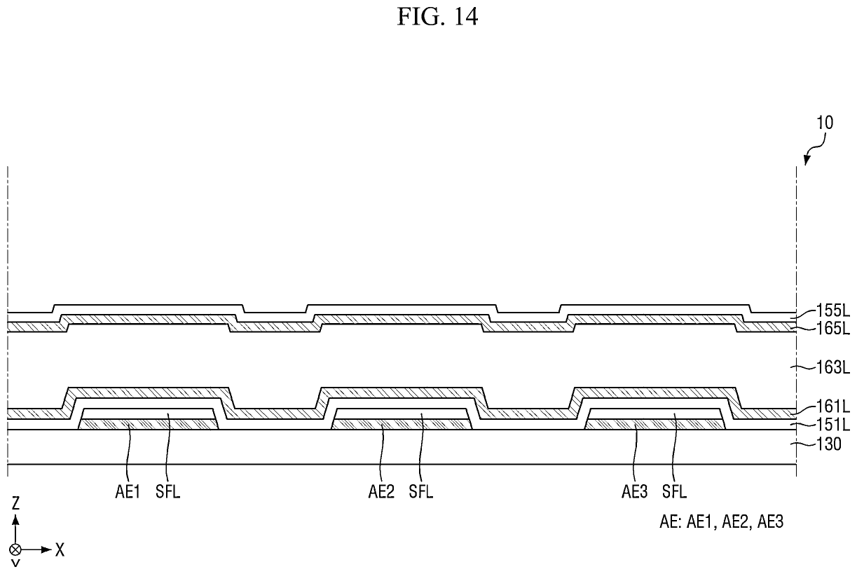

The display device 10 may include a sacrificial layer SFL (see FIG. 14) between the first pixel-defining layer 151 and the first to third anode electrodes AE1, AE2, and AE3 (see FIG. 14) during the fabrication process. The sacrificial layer SFL may be located between the first pixel-defining layer 151 and the first to third anode electrodes AE1, AE2, and AE3, and then may be partially removed via a subsequent wet-etching process. In doing so, a part of the sacrificial layer SFL that has not been removed may remain as residual patterns 153 between the first pixel-defining layer 151 and the first to third anode electrodes AE1, AE2, and AE3.

The first cathode electrode CE1 may completely cover the first emissive layer EL1, and the second cathode electrode CE2 may completely cover the second emissive layer EL2. In addition, the first emissive layer EL1 and the second emissive layer EL2 may contact parts of the first tips TIP1 of the first bank layer 161 to cover them.

The first inorganic layer 171-1 may completely cover the first light-emitting element ED1 in the first emission area EA1, and may partially cover the first electrode pattern CEP1 in the non-emission area NLA. In addition, the second inorganic layer 171-2 may completely cover the second light-emitting element ED2 in the second emission area EA2, and may partially cover the second electrode pattern CEP2 in the non-emission area NLA. The first inorganic layer 171-1 and the second inorganic layer 171-2 may be spaced apart from each other, exposing the second pixel-defining layer 155 in the non-emission area NLA.

In the non-emission area NLA, portions of the first organic pattern ELP1, the first electrode pattern CEP1 and the first inorganic layer 171-1, and portions of the second organic pattern ELP2, the second electrode pattern CEP2 and the second inorganic layer 171-2, may have a trench portion TP. In the display device 10, the fabrication process may include a process of etching portions of the first organic pattern ELP1, the first electrode pattern CEP1, the first inorganic layer 171-1, the second organic pattern ELP2, the second electrode pattern CEP2, and the second inorganic layer 171-2. The trench portion TP may be formed via the process of etching. The trench portion TP may be covered by the second encapsulation layer 173. The second encapsulation layer 173 and the third encapsulation layer 175 have been described above, and thus will not be described again.

Although the structures in the first emission area EA1 and the second emission area EA2 are shown and described for convenience of illustration, the structure in the third emission area EA3 may include the same features.

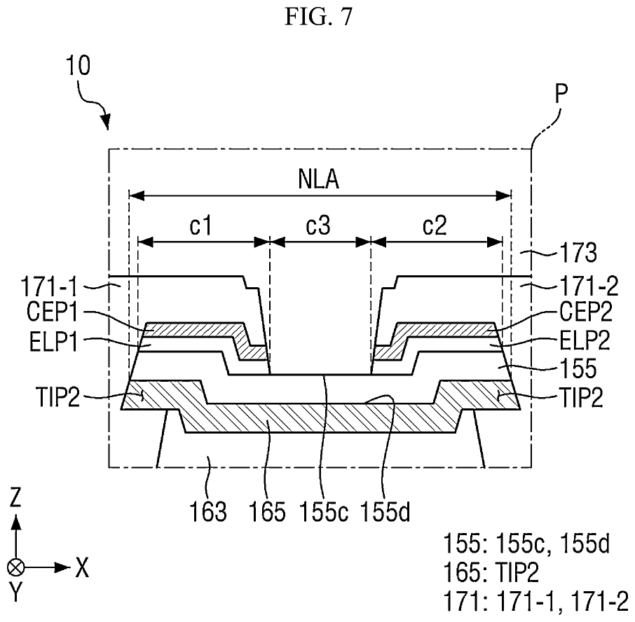

FIG. 7 is an enlarged cross-sectional view of area P of FIG. 6.

Referring to FIG. 7, the second pixel-defining layer 155 may overlap with, and may contact, the second tips TIP2 of the third bank layer 165.

According to some embodiments, the second pixel-defining layer 155 may include a first surface (e.g., top surface) 155c facing the second encapsulation layer 173, and a second surface (e.g., bottom surface) 155d facing the third bank layer 165.

According to some embodiments, the first surface 155c of the second pixel-defining layer 155 may be divided into a first portion c1, a second portion c2, and a third portion c3 according to the elements that the portions c1, c2, and c3 respectively contact. For example, the first portion c1 may contact the first organic pattern ELP1, the second portion c2 may contact the second organic pattern ELP2, and the third portion c3 may contact the second encapsulation layer 173. The first organic pattern ELP1 and the second organic pattern ELP2 may be spaced apart from each other with the third portion c3 of the second pixel-defining layer 155 therebetween (e.g., in plan view). That is to say, the first organic pattern ELP1 and the second organic pattern ELP2, the first electrode pattern CEP1 and the second electrode pattern CEP2, and the first inorganic layer 171-1 and the second inorganic layer 171-2 may be spaced apart from each other with the second encapsulation layer 173 therebetween. In other words, the first portion c1 may overlap with the first electrode pattern CEP1 and the first inorganic layer 171-1, and the second portion c2 may overlap with the second electrode pattern CEP2 and the second inorganic layer 171-2. The third portion c3 may overlap with none of the first organic pattern ELP1, the second organic pattern ELP2, the first electrode pattern CEP1, the second electrode pattern CEP2, the first inorganic layer 171-1, or the second inorganic layer 171-2.

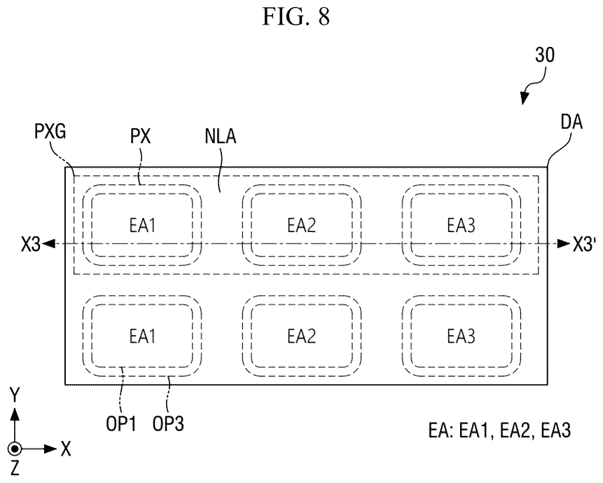

FIG. 8 is a plan view showing a layout of emission areas EA in the display area DA of FIG. 3 according to one or more other embodiments.

Referring to FIG. 8, the first to third emission areas EA1, EA2, and EA3 included in the display device 30 may be defined by first openings OP1 and second openings OP3. For example, the first openings OP1 may be defined by the first pixel-defining layer 151, and the second openings OP3 may be defined by the second pixel-defining layer 159, which will be described later. The second openings OP3 may completely surround the first openings OP1 when viewed from the top. The second openings OP3 may be completely surrounded by the non-emission area NLA when viewed from the top.

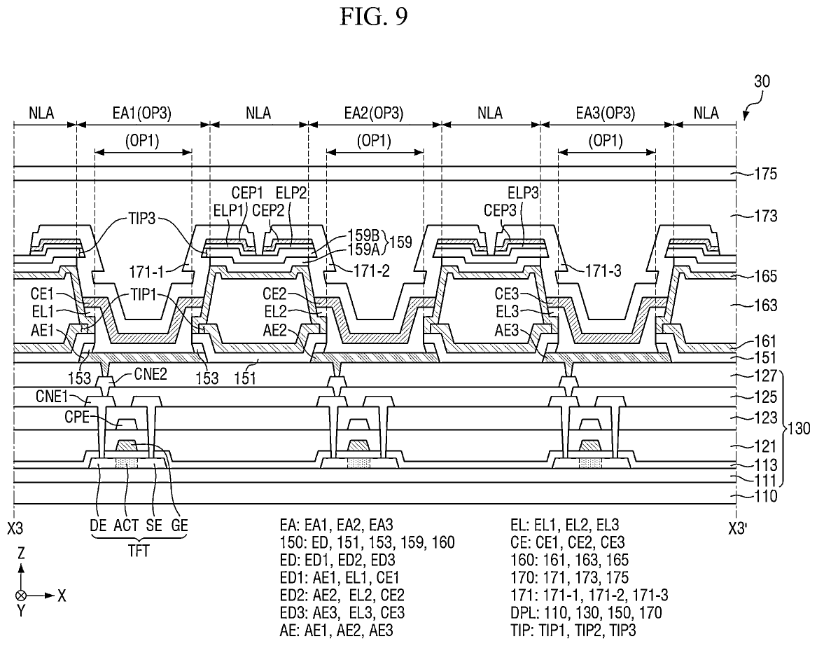

FIG. 9 is a cross-sectional view of the display layer DPL, taken along the line X3-X3 of FIG. 8. The display layer DPL may include a substrate 110, a thin-film transistor layer 130, a display element layer 150, a thin-film encapsulation layer 170. The substrate 110, the thin-film transistor layer 130, and the thin-film encapsulation layer 170 included in the display device 30 may include the same structure and features as type display device 10 according to one or more other embodiments. Therefore, the redundant descriptions will be omitted, and the structure of the display element layer 150 included in the display device 30 will be described.

According to the one or more embodiments corresponding to FIG. 9, the display element layer 150 may include light-emitting elements ED, a first pixel-defining layer 151, residual patterns 153, a second pixel-defining layer 159, and a bank structure 160.

The bank structure 160 may include a first bank layer 161, a second bank layer 163, and a third bank layer 165 located on the first pixel-defining layer 151. The first bank layer 161 may contact the first pixel-defining layer 151, and may include first tips TIP1 that protrude toward the emission areas EA from the second bank layer 163. The first bank layer 161 and the second bank layer 163 may include the same structure and features as the display device 10 described above, and redundant descriptions thereof will be omitted.

The third bank layer 165 may completely cover the second bank layer 163. In other words, the second bank layer 163 may be completely surrounded by the first bank layer 161 and the third bank layer 165. In addition, the third bank layer 165 may completely cover the first bank layer 161. It should be understood, however, that the present disclosure is not limited thereto. The third bank layer 165 may expose a part of the first bank layer 161 depending on a fabrication process.

The second pixel-defining layer 159 may be located on the bank structure 160. The second pixel-defining layer 159 may include a first layer 159A and a second layer 159B. The first layer 159A of the second pixel-defining layer 159 may contact the third bank layer 165 and may define second openings OP3. The first to third emission areas EA1, EA2, and EA3 may be defined by the second openings OP3. In addition, the second layer 159B of the second pixel-defining layer 159 may contact the first layer 159A, and may include second tips TIP3 that protrude toward the first to third emission areas EA1, EA2, and EA3 (e.g., in plan view) from the first layer 159A.

In the display device 30, as the second pixel-defining layer 159 includes the second tips TIP3, the first to third light-emitting elements ED1, ED2, and ED3 may be formed in the first to third emission areas EA1, EA2, and EA3, respectively, even without a fine metal mask during the process of fabricating the display device 30.

The second pixel-defining layer 159 may include an inorganic insulating material, for example, one of silicon oxide, silicon nitride, or silicon oxynitride. It should be noted that the first layer 159A and the second layer 159B may be made of different materials. For example, if the first layer 159A is made of silicon oxide, the second layer 159B may include silicon nitride and silicon oxynitride excluding silicon oxide. This may utilize different etch ratios of the first layer 159A and the second layer 159B in the fabrication process of the display device 30 to form the second tips TIP3 of the second pixel-defining layer 159.

The first to third organic patterns ELP1, ELP2, and ELP3 and the first to third electrode patterns CEP1, CEP2, and CEP3 may be located on the second pixel-defining layer 159. The first to third organic patterns ELP1, ELP2, and ELP3 and the first to third electrode patterns CEP1, CEP2, and CEP3 may be located to surround the first openings OP1.

The emissive layers EL may include a first emissive layer EL1, a second emissive layer EL2, and a third emissive layer EL3 located in the first to third emission areas EA1, EA2, and EA3, respectively. The emissive layers EL may contact the third bank layer 165 in the second openings OP3.

The residual patterns 153 may be located between the anode electrodes AE and the first pixel-defining layer 151 in the third direction (z-axis direction), and may contact the emissive layers EL.

The cathode electrodes CE may include a first cathode electrode CE1, a second cathode electrode CE2, and a third cathode electrode CE3 respectively located in the first to third emission areas EA1, EA2, and EA3. The cathode electrodes CE may contact the third bank layer 165 in the second openings OP3.

The first to third inorganic layers 171-1, 171-2, and 171-3 may respectively cover the first to third light-emitting elements ED1, ED2, and ED3 in the first openings OP1, and may cover the third bank layer 165 in the second openings OP3. The first to third inorganic layers 171-1, 171-2, and 171-3 may be different from the display device 10 according to one or more other embodiments, in that they are do not contact the second bank layer 163. In addition, the first to third inorganic layers 171-1, 171-2, and 171-3 may cover the second tips TIP3 of the second layer 159B.

The second encapsulation layer 173 may provide a flat surface over the first to third inorganic layers 171-1, 171-2, and 171-3 in the first opening OP1, and may contact the second layer 159B of the second pixel-defining layer 159 in the non-emission area NLA. In addition, the first encapsulation layer 171, the second encapsulation layer 173, and third encapsulation layer 175 included in the thin-film encapsulation layer 170 have been described above, and redundant descriptions thereof will be omitted.

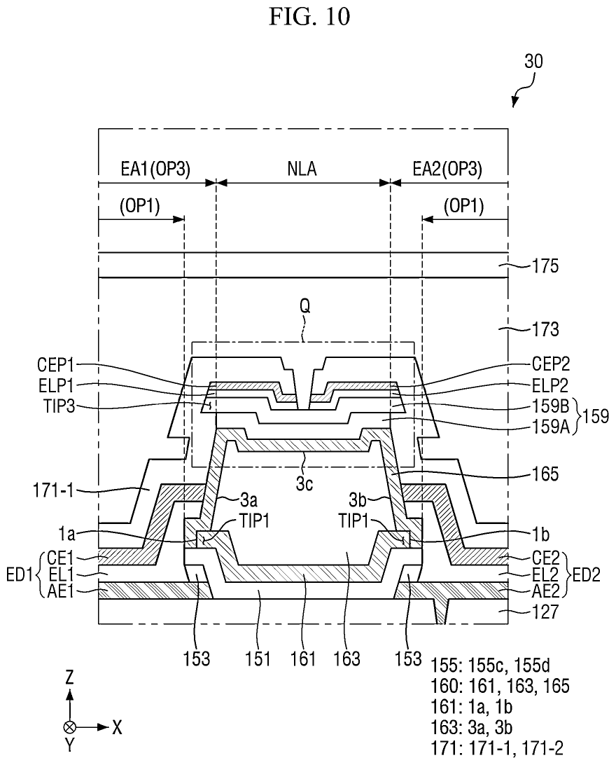

FIG. 10 is an enlarged cross-sectional view schematically showing the non-emission area NLA located between the first emission area EA1 and the second emission area EA2 in FIG. 9.

According to the one or more embodiments corresponding to FIG. 10, the first emission area EA1 and the second emission area EA2 may be spaced apart from each other with the non-emission area NLA therebetween. As described above, first openings OP1 may be defined by the first pixel-defining layer 151, and second openings OP3 may be defined by the second pixel-defining layer 159.

According to some embodiments, the first bank layer 161 may include a first side surface 1a facing the first emission area EA1 and a second side surface 1b facing the second emission area EA2. The first side surface 1a of the first bank layer 161 may protrude from the second bank layer 163 toward the first emission area EA1, and the second side surface 1b of the first bank layer 161 may protrude from the second bank layer 163 toward the second emission area EA2. That is to say, the first bank layer 161 may have first tips TIP1 protruding toward the first and second emission areas EA1 and EA2.

According to some embodiments, the second bank layer 163 may include a first side surface 3a, a second side surface 3b, and a first surface (e.g., top surface) 3c. The first side surface 3a may face the first emission area EA1, the second side surface 3b may face the second emission area EA2, and the first surface 3c may face the second pixel-defining layer 159. The first side surface 3a and the second side surface 3b may be connected by the first surface 3c.

The third bank layer 165 may contact the first side surface 3a, the second side surface 3b, and the first surface 3c of the second bank layer 163. In other words, the third bank layer 165 may completely cover the first side surface 3a, the second side surface 3b, and the first surface 3c of the second bank layer 163.

The second pixel-defining layer 159 will be described later.

The first cathode electrode CE1 and the second cathode electrode CE2 may be electrically connected with each other through the third bank layer 165 and the second bank layer 163.

The residual patterns 153 may overlap with the first tips TIP1 of the first bank layer 161, and the second tips TIP3 of the second layer 159B of the second pixel-defining layer 159, in the third direction (z-axis direction).

The first inorganic layer 171-1 may completely cover the first light-emitting element ED1 in the first openings OP1, and may completely cover the third bank layer 165, the second pixel-defining layer 159, the first organic pattern ELP1, and the first electrode pattern CEP1 in the second openings OP3. In addition, the first inorganic layer 171-1 may cover a portion of the first electrode pattern CEP1 in the non-emission area NLA. In other words, the first inorganic layer 171-1 may contact the first cathode electrode CE1, the third bank layer 165, the second pixel-defining layer 159, the first organic pattern ELP1, and the first electrode pattern CEP1.

In addition, the second inorganic layer 171-2 may completely cover the second light-emitting element ED2 in the first opening OP1, and may completely cover the third bank layer 165, the second pixel-defining layer 159, the second organic pattern ELP2, and the second electrode pattern CEP2 in the second opening OP3. In addition, the second inorganic layer 171-2 may cover a portion of the second electrode pattern CEP2 in the non-emission area NLA. In other words, the second inorganic layer 171-2 may contact the second cathode electrode CE2, the third bank layer 165, the second pixel-defining layer 159, the second organic pattern ELP2, and the second electrode pattern CEP2. Other redundant descriptions will be omitted.

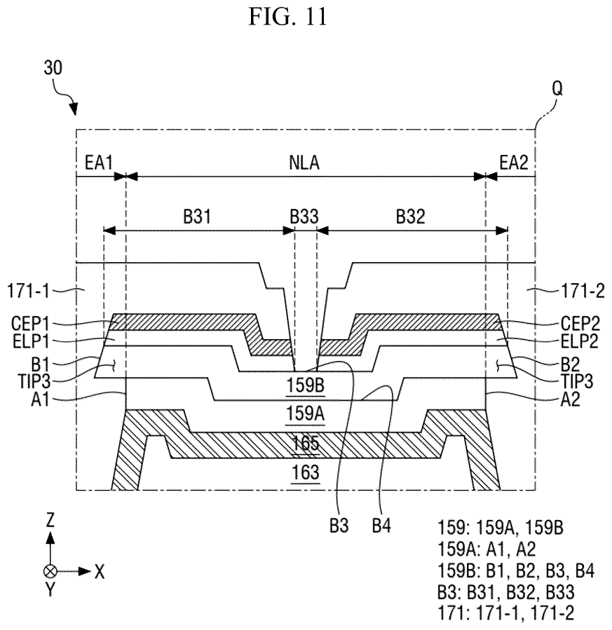

FIG. 11 is an enlarged cross-sectional view of area Q of FIG. 10.

According to the one or more embodiments corresponding to FIG. 11, the first layer 159A of the second pixel-defining layer 159 included in the display device 30 may contact the third bank layer 165.

According to some embodiments, the first layer 159A of the second pixel-defining layer 159 may include a first side surface A1 facing the first emission area EA1 and a second side surface A2 facing the second emission area EA2. In addition, the second layer 159B of the second pixel-defining layer 159 may include a first side surface B1, a second side surface B2, a first surface (e.g., top surface) B3, and a second surface (e.g., bottom surface) B4. For example, the first side surface B1 may face the first emission area EA1, the second side surface B2 may face the second emission area EA2, the first surface B3 may face the second encapsulation layer 173, and the second surface B4 may face the first layer 159A. The first side surface B1 and the second side surface B2 may be connected by the first surface B3 and the second surface B4, and the first surface B3 and the second surface B4 may be opposite to each other.

According to some embodiments, the first side surface B1 of the second layer 159B may protrude toward the first emission area EA1 from (e.g., beyond) the first side surface A1 of the first layer 159A in the first direction (x-axis direction). In addition, the second side surface B2 of the second layer 159B may protrude toward the second emission area EA2 from the second side surface A2 of the second layer 159B in the first direction (x-axis direction). Therefore, the second layer 159B may have second tips TIP3 respectively protruding at both sides of the first layer 159A in the first direction (x-axis direction). That is to say, undercuts may be formed between the second tip TIP3 and the first side surface A1, and between the second tip TIP3 and the second side surface A2.

According to some embodiments, the first surface B3 of the second layer 159B may be divided into a first portion B31, a second portion B32, and a third portion B33 according to the elements that the portions B31, B32, and B33 respectively contact. For example, the first portion B31 may contact the first organic pattern ELP1, the second portion B32 may contact the second organic pattern ELP2, and the third portion B33 may contact the second encapsulation layer 173. The first organic pattern ELP1 and the second organic pattern ELP2 may be spaced apart from each other with the third portion B33 of the second pixel-defining layer 159 therebetween (e.g., in plan view). That is to say, the first organic pattern ELP1 and the second organic pattern ELP2, the first electrode pattern CEP1 and the second electrode pattern CEP2, and the first inorganic layer 171-1 and the second inorganic layer 171-2 may be spaced apart from each other with the second encapsulation layer 173 therebetween (e.g., in plan view).

In other words, the first portion B31 may overlap with the first electrode pattern CEP1 and the first inorganic layer 171-1, and the second portion B32 may overlap with the second electrode pattern CEP2 and the second inorganic layer 171-2. The third portion B33 may overlap with none of the first organic pattern ELP1, the second organic pattern ELP2, the first electrode pattern CEP1, the second electrode pattern CEP2, the first inorganic layer 171-1, or the second inorganic layer 171-2.

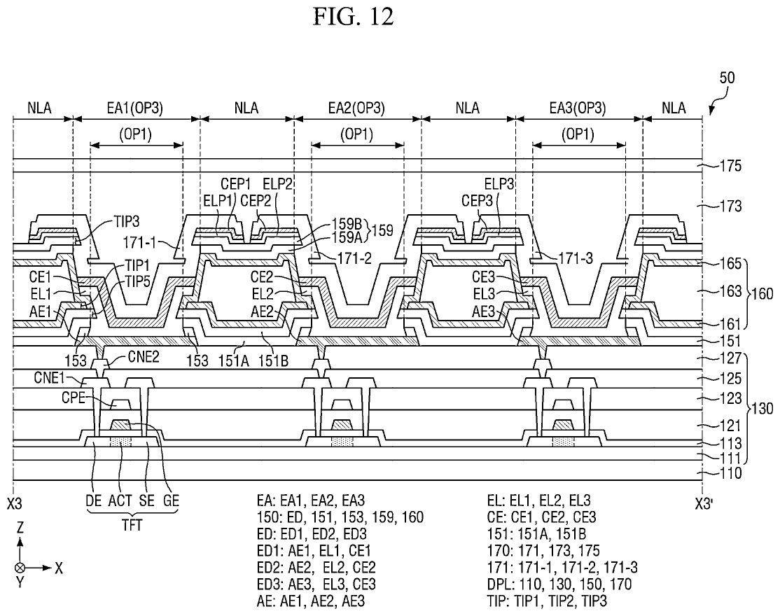

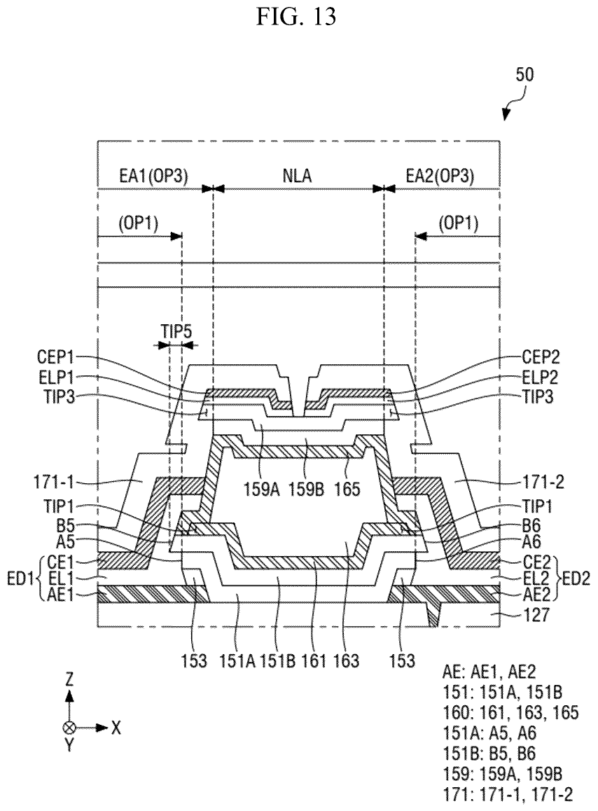

FIG. 12 is a cross-sectional view of the display layer DPL, taken along the line X3-X3 of FIG. 8 according to one or more other embodiments. FIG. 13 is an enlarged cross-sectional view schematically showing the non-emission area NLA located between the first emission area EA1 and the second emission area EA2 in FIG. 12.

The display layer DPL may include a substrate 110, a thin-film transistor layer 130, a display element layer 150, a thin-film encapsulation layer 170. The substrate 110, the thin-film transistor layer 130, and the thin-film encapsulation layer 170 included in the display device 50 may include the same structure and features as the display device 30 described above. Therefore, the redundant descriptions will be omitted, and the structure of the display element layer 150 included in the display device 50 will be described.

According to the one or more embodiments corresponding to FIGS. 12 and 13, the display element layer 150 may include light-emitting elements ED, a first pixel-defining layer 151, residual patterns 153, a second pixel-defining layer 159, and a bank structure 160. The first pixel-defining layer 151 is different from that of the display device 30 described above, in that the former includes a first layer 151A and a second layer 151B. Other redundant descriptions will be omitted.

As shown in FIG. 13, the first layer 151A included in the first pixel-defining layer 151 may be located on a second via layer 127 and an anode electrode AE. The first layer 151A may define first openings OP1.

According to some embodiments, the first layer 151A may include a first side surface A5 facing the first emission area EA1, and a second side surface A6 facing the second emission area EA2.

In addition, the second layer 151B of the first pixel-defining layer 151 may be located on the first layer 151A in contact therewith. In other words, the second layer 151B may be located between the first layer 151A and the first bank layer 161.

According to some embodiments, the second layer 151B may include a first side surface B5 facing the first emission area EA1, and a second side surface B6 facing the second emission area EA2. The first side surface B5 of the second layer 151B may protrude toward the first emission area EA1 from the first side surface A5 of the first layer 151A in the first direction (x-axis direction). In addition, the second side surface B6 of the second layer 151B may protrude toward the second emission area EA2 from the second side surface A6 of the second layer 151B in the first direction (x-axis direction). Therefore, the second layer 151B may have third tips TIP5 protruding at both sides of the first layer 151A in the first direction (x-axis direction). Undercuts may be formed between the third tip TIP5 and the first side surface A5, and between the third tip TIP5 and the second side surface A6.

As the display device 50 includes the third tips TIP5, the first to third light-emitting elements ED1, ED2, and ED3 can be formed without a fine metal mask during the process of fabricating the display device 50. In addition, as the display device 50 includes the third tips TIP5, the first to third emissive layers EL1, EL2, and EL3 and the first to third cathode electrodes CE1, CE2, and CE3 can be connected without being disconnected.

According to some embodiments, the first pixel-defining layer 151 may include an inorganic insulating material, for example, one of silicon oxide, silicon nitride, or silicon oxynitride. It should be noted that the first layer 151A and the second layer 151B may be made of different materials. For example, when the first layer 151A is made of silicon oxide, the second layer 151B may include silicon nitride and silicon oxynitride excluding silicon oxide. This may utilize different etch ratios of the first layer 151A and the second layer 151B in the fabrication process of the display device 50 to form the third tips TIP5 of the second layer 151B.

The first emissive layer EL1 and the second emissive layer EL2 may contact the third tips TIP5 of the first pixel-defining layer 151 to cover them. Other redundant descriptions will be omitted.

The bank structure 160 may be located on the second layer 151B of the first pixel-defining layer 151 in contact therewith. The bank structure 160 may include a first bank layer 161, a second bank layer 163, and a third bank layer 165. The first bank layer 161 may include the first tips TIP1 that protrude toward the first and second emission areas EA1 and EA2 from the second bank layer 163. The third bank layer 165 may completely cover the second bank layer 163. The first tips TIP1 may not overlap with the third tips TIP3 in the third direction (z-axis direction). In addition, a portion of the third bank layer 165 may overlap with the third tip TIP3 in the third direction (z-axis direction), and a portion of the third bank layer 165 may contact the third tip TIP3. Other redundant descriptions will be omitted.

The second pixel-defining layer 159 may be located on the bank structure 160. The second pixel-defining layer 159 may include a first layer 159A and a second layer 159B, and the first layer 159A of the second pixel-defining layer 159 may define second openings OP3. In addition, the second layer 159B of the second pixel-defining layer 159 may include second tips TIP3 that protrude toward the first to second emission areas EA1 and EA2 from the first layer 159A. Other redundant descriptions will be omitted.

FIGS. 14 to 25 are schematic cross-sectional views showing a method of fabricating the display device 10 shown in FIG. 5. Hereinafter, a process of fabricating the display layer DPL shown in FIG. 5 will be described in terms of the order of forming the layers.

Referring to FIG. 14, anode electrodes AE, a sacrificial layer SFL, a first pixel-defining material layer 151L, first to third bank material layers 161L, 163L, and 165L, and a second pixel-defining material layer 155L may be formed on a thin-film transistor layer 130. In one or more embodiments, the thin-film transistor layer 130 may be located on the substrate 110, and the structure of the thin-film transistor layer 130 has been described above with reference to FIG. 5, and redundant descriptions thereof will be omitted.

The anode electrodes AE may include first to third anode electrodes AE1, AE2, and AE3 spaced apart from each other on the thin-film transistor layer 130. The sacrificial layer SFL may be located on each of the first to third anode electrodes AE1, AE2, and AE3. The sacrificial layer SFL may help reduce or prevent the likelihood of the top surfaces of the first to third anode electrodes AE1, AE2, and AE3 contacting the first pixel-defining material layer 151L.

The sacrificial layer SFL may include an oxide semiconductor. For example, the sacrificial layer SFL may include at least one of indium-gallium-zinc oxide (IGZO), zinc-tin oxide (ZTO), indium-tin oxide (IZO), etc.

The first pixel-defining material layer 151L, the first to third bank material layers 161L, 163L, and 165L, and the second pixel-defining material layer 155L may be located over the first to third anode electrodes AE1, AE2, and AE3 and the sacrificial layer SFL. The first pixel-defining material layer 151L may be located to entirely cover the sacrificial layer SFL and the thin-film transistor layer 130, and the first to third bank material layers 161L, 163L, and 165L may be located to entirely cover the first pixel-defining material layer 151L. The first bank material layer 161L may be located directly on the first pixel-defining material layer 151L, and the second bank material layer 163L and the third bank material layer 165L may be sequentially located on the first bank material layer 161L. The second pixel-defining material layer 155L may be located to entirely cover the third bank material layer 165L.

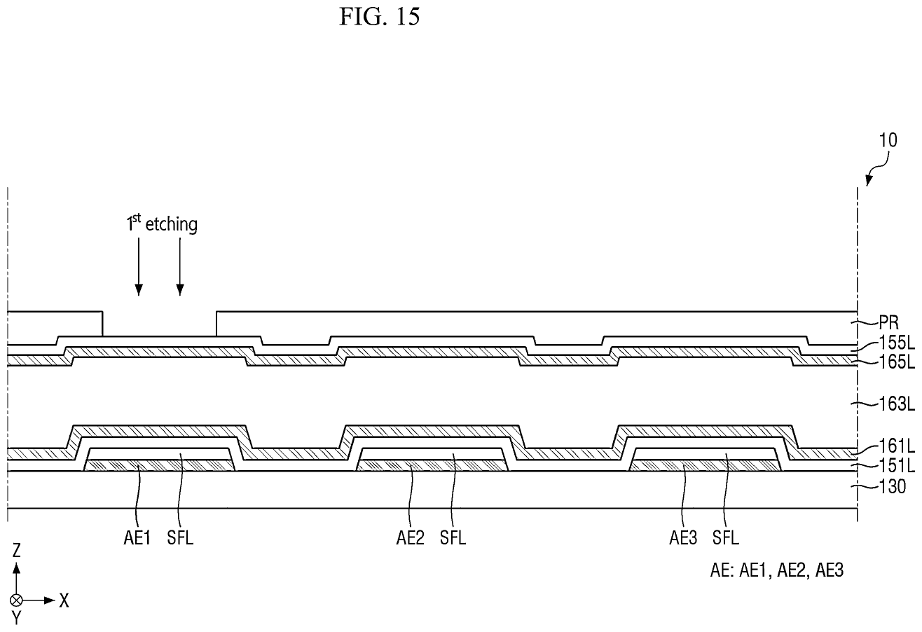

Subsequently, referring to FIG. 15, a photoresist PR may be formed on the second pixel-defining material layer 155L except for the portion overlapping with the first anode electrode AE1. Subsequently, the first bank material layer 161L, the second bank material layer 163L, the third bank material layer 165L, and the second pixel-defining material layer 155L are partially etched using the photoresist PR as a mask (1st etching).

According to one or more embodiments, the first (1st) etching process may be carried out as dry etching. As the first etching process (1st etching) is performed as a dry-etching process, the portions of the first pixel-defining material layer 151L, the first to third bank material layers 161L, 163L, and 165L, and the second pixel-defining material layer 155L that overlap with the first anode electrode AE1 may be isotropically etched.

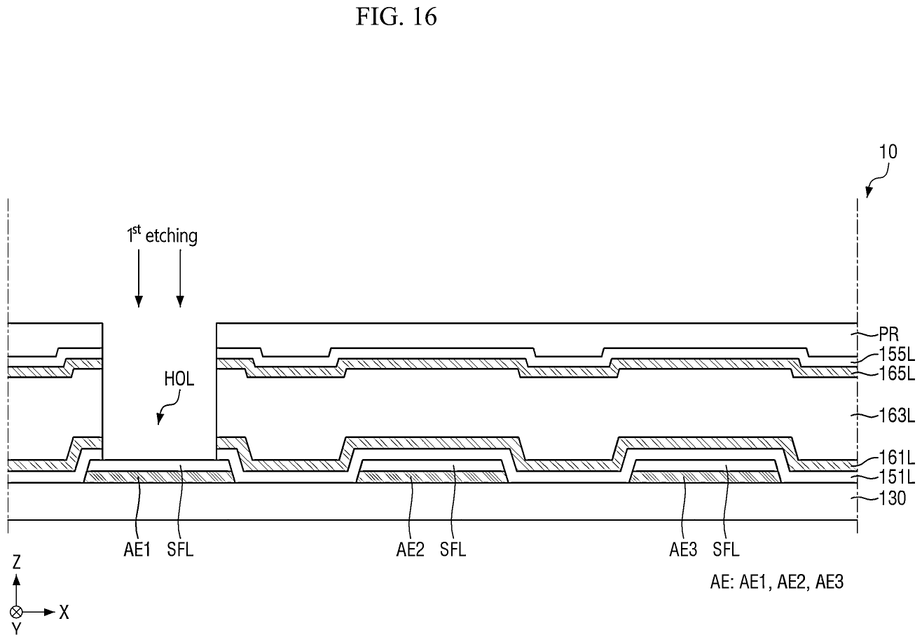

Via this process, as shown in FIG. 16, a hole HOL may be formed at the portion overlapping with the first anode electrode AE1, and the sacrificial layer SFL located on the first anode electrode AE1 may be exposed.

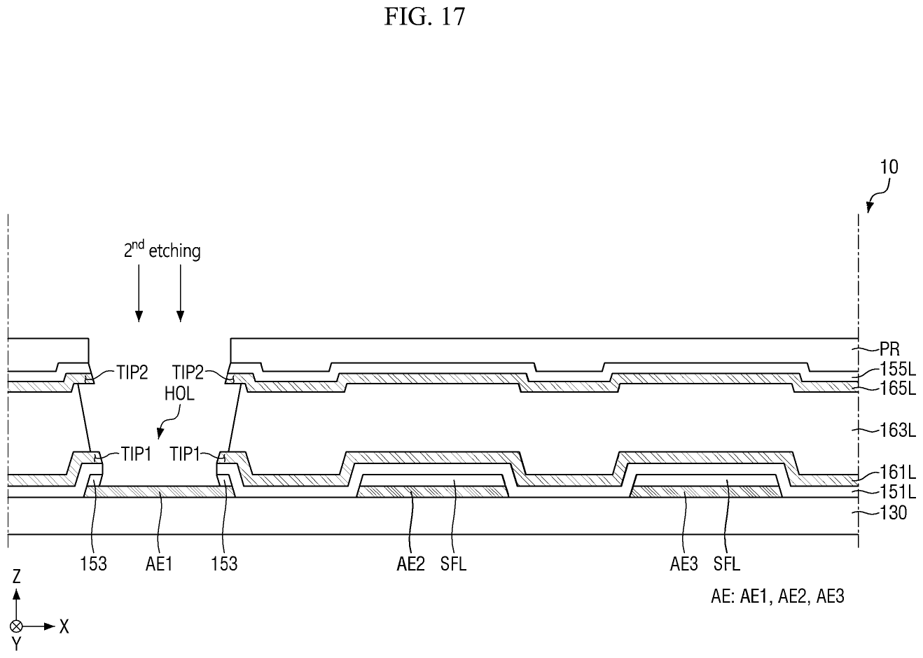

Subsequently, referring to FIG. 17, the inside of the hole HOL formed in line with the first anode electrode AE1 is etched (2^{nd} etching). According to one or more embodiments, the second etching process may be performed as a wet-etching process.

The first bank material layer 161L and the third bank material layer 165L may have an etch rate that is lower than the etch rate of the second bank material layer 163L. Accordingly, the side surface of the first bank material layer 161L may form a first tip TIP1 that protrudes toward the hole HOL from the side surface of the second bank material layer 163L, and the side surface of the third bank material layer 165L may form a second tip TIP2 that protrudes toward the hole HOL from the side surface of the second bank material layer 163L.

In addition, the first pixel-defining material layer 151L and the second pixel-defining material layer 155L includes different inorganic materials, and thus may have different respective etch ratios. Accordingly, the first pixel-defining material layer 151L and the second pixel-defining material layer 155L may have different shapes even though they are formed via the same process.

At the same time, the sacrificial layer SFL located on the first anode electrode AE1 may be partially removed via this process. It should be noted that the sacrificial layer SFL may not be completely removed, but may remain in the space between the first pixel-defining material layer 151L and the first electrode AE1 as a residual pattern 153.

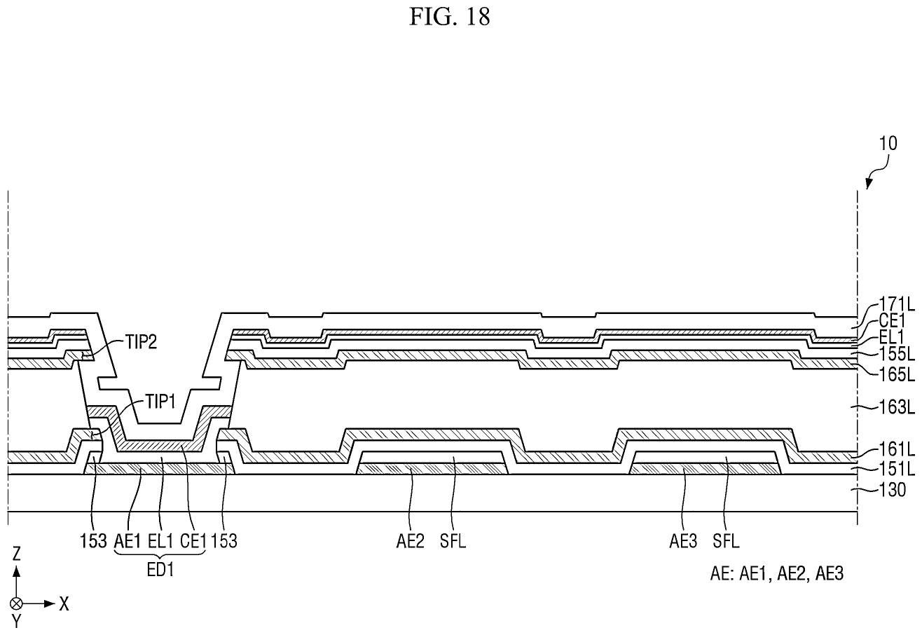

Subsequently, referring to FIG. 18, a first emissive layer EL1 and a first cathode electrode CE1 are deposited on the first anode electrode AE1. The first emissive layer EL1 and the first cathode electrode CE1 may be formed via a thermal evaporation process.

As the display device 10 includes the first tip TIP1 and the second tip TIP2, the first emissive layer EL1 and the first cathode electrode CE1 can be formed on the first anode electrode AE1 without a fine metal mask.

It should be noted that the deposition process of forming the first emissive layer EL1 may be performed at an angle of about 45° to about 50° from the upper surface of the first anode electrode AE1. Accordingly, the first emissive layer EL1 may be formed to fill the space between the first anode electrode AE1 and the first pixel-defining material layer 151L, and may be formed also on a part of the side surface of the second bank material layer 163L hidden by the second tip TIP.

The deposition process of forming the first cathode electrode CE1 may be performed at an angle of about 30° or less from the upper surface of the first anode electrode AE1. In other words, the deposition process of forming the first cathode electrode CE1 may be performed in a relatively horizontal direction compared to the deposition process of forming the first emissive layer EL1. Accordingly, the first cathode electrode CE1 may completely cover the first emissive layer EL1, and may also be formed on a part of the side surface of the second bank material layer 163L hidden by the second tip TIP2. In this manner, the first light-emitting element ED1 can be formed.

The first emissive layer EL1 and the first cathode electrode CE1 may be located not only on the first anode electrode AE1, but also on the second pixel-defining material layer 155L. In other words, the first emissive layer EL1 and the first cathode electrode CE1 may be located on the second pixel-defining material layer 155L above the second anode electrode AE2 and the third anode electrode AE3.

Subsequently, a first encapsulation material layer 171L covering the first cathode electrode CE1 is formed on the entire surface. The first encapsulation material layer 171L may be formed via a chemical vapor deposition (CVD) process. The first encapsulation material layer 171L may form a uniform film regardless of the underlying structure having different heights. For example, the first encapsulation material layer 171L may also cover the step formed by the first light-emitting element ED1, and may also cover the undercut formed by the second tip TIP2 and the second bank material layer 163L. In addition, the first encapsulation material layer 171L may entirely cover the first cathode electrode CE1 located on the second pixel-defining material layer 155L.

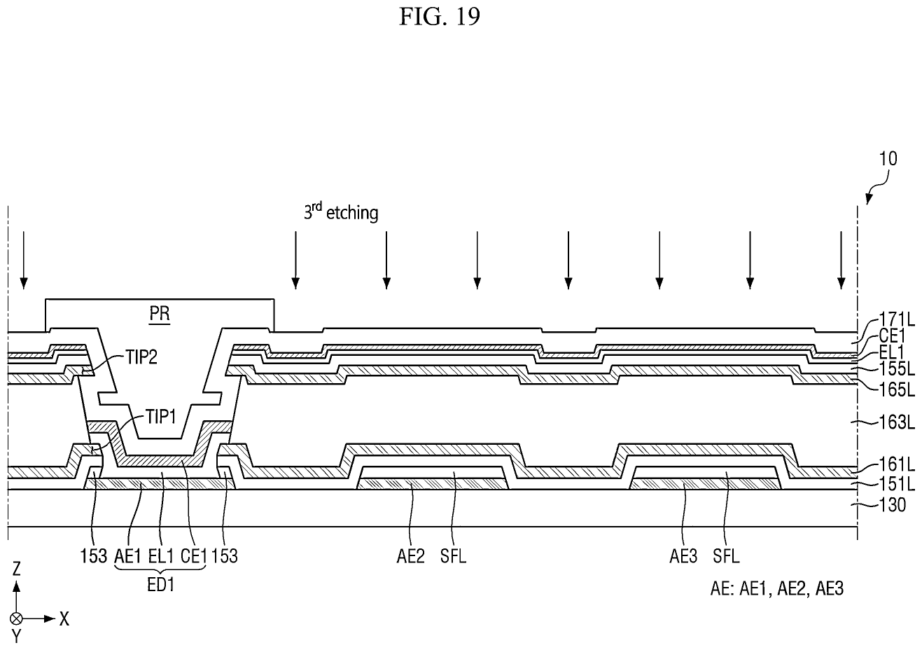

Referring to FIG. 19, a photoresist PR is formed over the first light-emitting element ED1 and the periphery of the first light-emitting element ED1, and an etching process is performed leaving the first light-emitting element ED1 and the periphery of the first light-emitting element ED1 (3^{rd} etching). For example, the third etching process may be carried out by alternately performing a wet-etching process and a dry-etching process. In this process, the first emissive layer EL1, the first cathode electrode CE1, and the first encapsulation material layer 171L where the photoresist PR is not formed may all be removed.

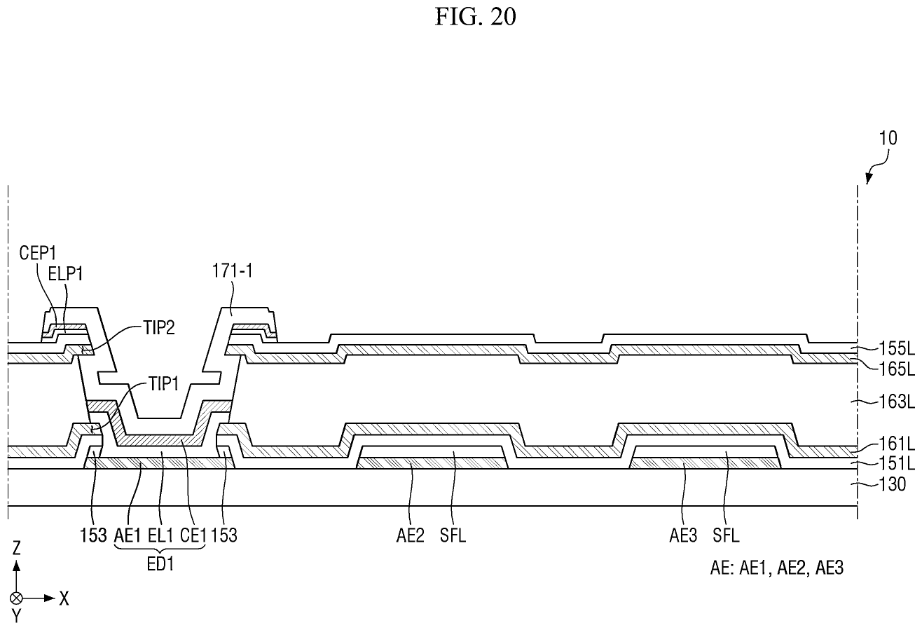

Via this process, as shown in FIG. 20, the first inorganic layer 171-1 may be formed, and the first emissive layer EL1 and the first cathode electrode CE1 located on the second pixel-defining material layer 155L may be formed into a first organic pattern ELP1 and a first electrode pattern CEP1.

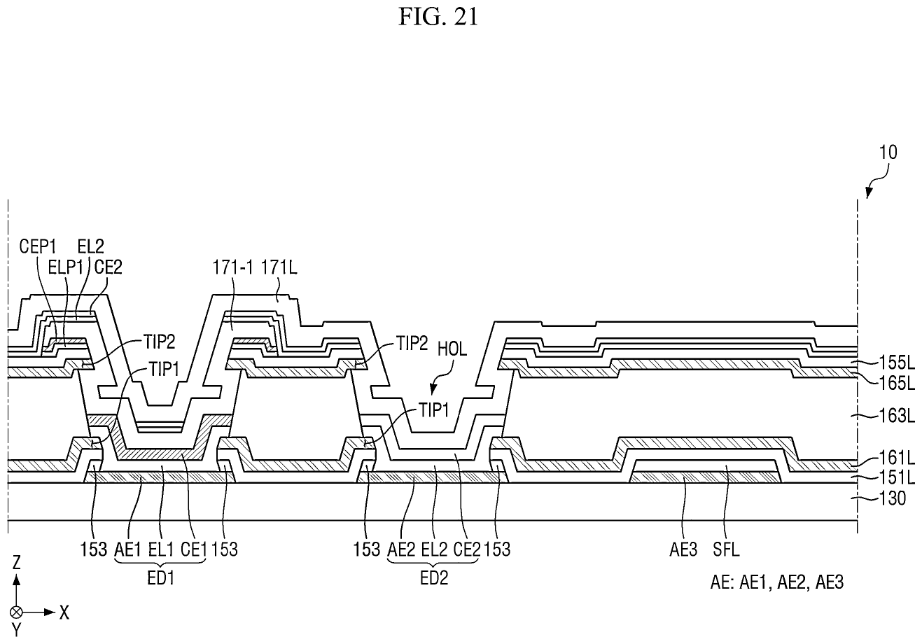

Subsequently, referring to FIGS. 21 to 23, the above-described processes are repeated to form a second light-emitting element ED2. For example, a photoresist PR is formed so that the portion overlapping with the second anode electrode AE2 is exposed, and a hole HOL is formed in the portion overlapping with the second anode electrode AE2 via a dry-etching process. Subsequently, portions of the first to third bank material layers 161L, 163L, and 165L that overlap with the inside of the hole HOL may be wet-etched to form a first tip TIP1 of the first bank material layer 161L and a second tip TIP2 of the third bank material layer 165L.

Subsequently, the second emissive layer EL2, the second cathode electrode CE2 and the first encapsulation material layer 171L are deposited on the entire surface. In this process, the second emissive layer EL2, the second cathode electrode CE2 and the first encapsulation material layer 171L are formed on the second anode electrode AE2, so that the second light-emitting element ED2 can be formed.

In addition, the second emissive layer EL2, the second cathode electrode CE2 and the first encapsulation material layer 171L may be formed entirely over the first anode electrode AE1 and the third anode electrode AE3. Therefore, the second emissive layer EL2, the second cathode electrode CE2, and the first encapsulation material layer 171L formed in this process may be located on the first inorganic layer 171-1.

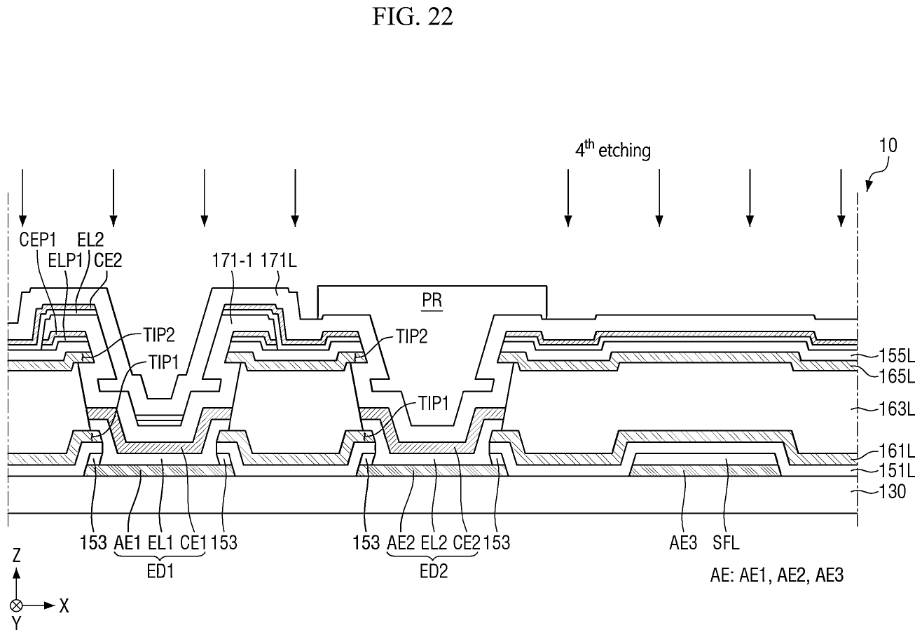

Subsequently, as shown in FIG. 22, a photoresist PR is formed over the second light-emitting element ED2 and the periphery of the second light-emitting element ED2, and an etching process is performed leaving the second light-emitting element ED2 and the periphery of the second light-emitting element ED2 (4^{th} etching). For example, the fourth etching process may be carried out by alternately performing a wet-etching process and a dry-etching process. In this process, the second emissive layer EL2, the second cathode electrode CE2, and the first encapsulation material layer 171L where the photoresist PR is not formed may all be removed.

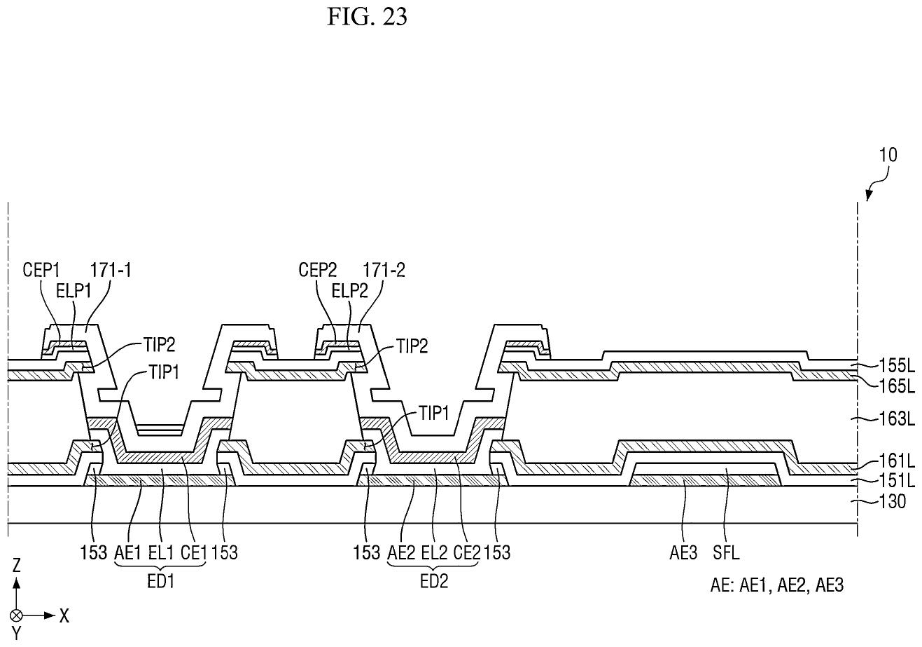

Via this process, as shown in FIG. 23, the second inorganic layer 171-2 may be formed, and the second emissive layer EL2 and the second cathode electrode CE2 located on the second pixel-defining material layer 155L may be formed into a second organic pattern ELP2 and a second electrode pattern CEP2.

As described above, in the display device 10, an etching process may be performed repeatedly. In general, when a metal material is exposed to an etchant during an etching process, the metal material may cause arc faults. It should be noted that the display device 10 includes the second pixel-defining material layer 155L on the third bank material layer 165L including a metal material, so that it is possible to protect the metal material from being exposed to the etchant during repeated etching processes. Accordingly, the display device 10 can solve arc faults caused during the fabrication process.

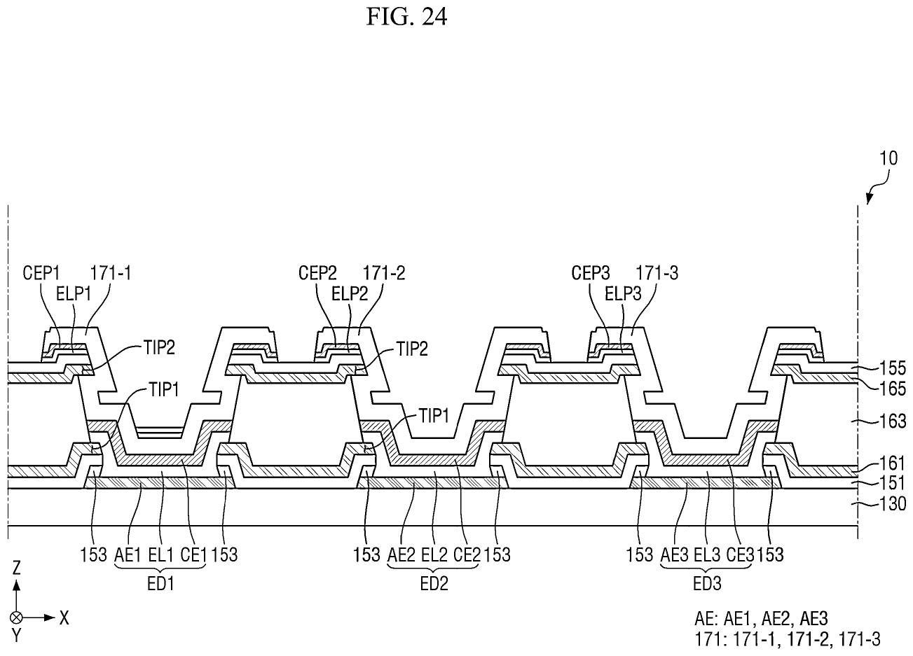

Subsequently, referring to FIG. 24, the above-described processes are repeated to form a third light-emitting element ED3 and a third inorganic layer 171-3. Descriptions of the repeated processes are omitted. Via this process, the third emissive layer EL3 and the third cathode electrode CE3 located on the second pixel-defining material layer 155L will be formed into a third organic pattern ELP3 and a third electrode pattern CEP3.

Via this process, the first pixel-defining material layer 151L may be formed into the first pixel-defining layer 151 shown in FIG. 5, the first bank material layer 161L may be formed into the first bank layer 161, the second bank material layer 163L may be formed into the second bank layer 163, and the third bank material layer 165L may be formed into the third bank layer 165. In addition, the second pixel-defining material layer 155L may be formed into the second pixel-defining layer 155.

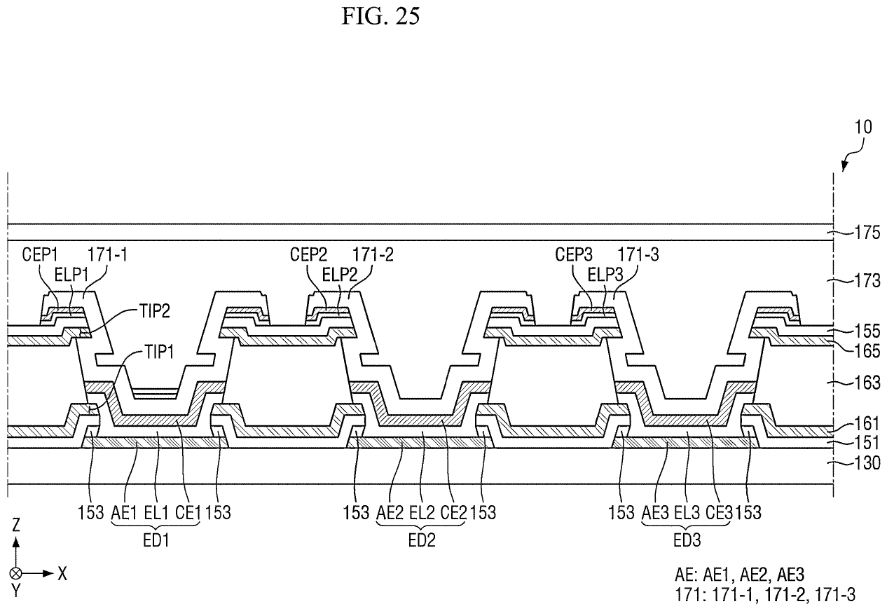

Subsequently, referring to FIG. 25, a second encapsulation layer 173 may be formed on the entire surface to provide a flat surface over the first encapsulation layer 171 having different heights, and then a third encapsulation layer 175 may be formed on the entire second encapsulation layer 173, so that the display element layer 150 of the display device 10 shown in FIG. 5 can be formed.

As described above, as the display device 10 includes the first tips TIP1 of the first bank layer 161, and the second tips TIP2 of the third bank layer 165, the first to third light-emitting elements ED1, ED2, and ED3 spaced apart from one another can be formed without a fine metal mask. In addition, as the display device 10 includes the second pixel-defining layer 155 on the third bank layer 165, it is possible to prevent arc faults caused during the fabrication process.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of aspects within each embodiment should typically be considered as available for other similar aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising an emission area and a non-emission area;
a first anode electrode at the emission area;
a first cathode electrode above the first anode electrode;
a first pixel-defining layer at the non-emission area, and defining a first opening;
a bank structure above the first pixel-defining layer, and comprising a second bank layer contacting the first cathode electrode, and a third bank layer comprising a second tip protruding toward the emission area from a side surface of the second bank layer;
a second pixel-defining layer above the bank structure, defining a second opening, overlapping the second tip in a direction perpendicular to the substrate, and contacting the second tip; and
a first encapsulation layer above the second pixel-defining layer.

2. The display device of claim 1, further comprising a first bank layer between the first pixel-defining layer and the second bank layer, contacting the first pixel-defining layer, and comprising a first tip protruding toward the emission area from the side surface of the second bank layer.

3. The display device of claim 2, wherein the second bank layer has higher electrical conductivity than the first bank layer and the third bank layer.

4. The display device of claim 3, wherein the first cathode electrode covers the first tip.

5. The display device of claim 4, wherein the first pixel-defining layer and the second pixel-defining layer comprise different respective inorganic materials.

6. The display device of claim 4, further comprising a residual pattern between the first anode electrode and the first pixel-defining layer in a direction perpendicular to the substrate, and overlapping the first tip and the second tip in the direction perpendicular to the substrate.

7. The display device of claim 1, wherein the first opening is completely surrounded by the second opening in plan view.

8. The display device of claim 1, further comprising:
a second anode electrode spaced apart from the first anode electrode with the first pixel-defining layer therebetween; and
a second cathode electrode above the second anode electrode, contacting the second bank layer, and electrically connected to the first cathode electrode by the second bank layer.

9. The display device of claim 8, further comprising a second encapsulation layer above the first encapsulation layer, and comprising an organic material,
wherein the first encapsulation layer comprises a first inorganic layer covering the first cathode electrode, and a second inorganic layer covering the second cathode electrode and separated from the first inorganic layer by the second encapsulation layer at the non-emission area.

10. The display device of claim 9, wherein the second pixel-defining layer comprises a first surface facing the second encapsulation layer and comprising a first portion overlapping the first inorganic layer, a second portion overlapping the second inorganic layer, and a third portion contacting the second encapsulation layer between the first portion and the second portion.

11. The display device of claim 9, further comprising:
a first electrode pattern above the second pixel-defining layer, spaced apart from the first cathode electrode, and comprising a same material as the first cathode electrode; and
a second electrode pattern above the second pixel-defining layer, spaced apart from the second cathode electrode, and comprising a same material as the second cathode electrode.

12. The display device of claim 11, wherein the first electrode pattern and the second electrode pattern are spaced apart from each other in a direction parallel to the substrate with the second encapsulation layer therebetween.

13. A display device comprising:
a substrate comprising an emission area and a non-emission area;
an anode electrode at the emission area;
a cathode electrode above the anode electrode;
a first pixel-defining layer at the non-emission area and defining a first opening;
a bank structure above the first pixel-defining layer, and comprising a first bank layer, a second bank layer, and a third bank layer stacked on one another in a direction perpendicular to the substrate; and
a second pixel-defining layer above the bank structure, defining a second opening, and comprising a first layer contacting the third bank layer, and a second layer above the first layer and comprising a second tip protruding toward the emission area from a side surface of the first layer.

14. The display device of claim 13, wherein the second bank layer is completely surrounded by the first bank layer and the third bank layer.

15. The display device of claim 14, wherein the cathode electrode contacts the third bank layer.

16. The display device of claim 14, wherein the first bank layer comprises a first tip protruding toward the emission area from a side surface of the second bank layer and overlapping the second tip in a direction perpendicular to the substrate.

17. The display device of claim 16, wherein the first layer and the second layer comprise different respective inorganic materials.

18. The display device of claim 15, wherein the first pixel-defining layer comprises a third layer facing the substrate, and a fourth layer above the third layer and comprising a first tip protruding toward the emission area from a side surface of the third layer.

19. The display device of claim 18, wherein the first tip is in the first opening.

20. A method of fabricating a display device, the method comprising:
preparing a substrate comprising an emission area and a non-emission area;
forming an anode electrode at the emission area;
forming a sacrificial layer above the anode electrode;
forming a first pixel-defining material layer completely covering the sacrificial layer and the substrate;
forming a bank material layer completely covering the first pixel-defining material layer;
forming a second pixel-defining material layer;
forming a photoresist above the bank material layer;
removing portions of the first pixel-defining material layer, the bank material layer, and the second pixel-defining material layer overlapping the anode electrode via an etching process to form a hole exposing the sacrificial layer;
removing an inner sidewall of the hole via an etching process to expose the anode electrode;
forming a first pixel-defining layer, a second pixel-defining layer, and a bank structure protected by the second pixel-defining layer from an etchant during the etching process, and comprising a stacked structure of a second bank layer, a first bank layer above the second bank layer and comprising a first tip protruding toward the emission area from a side surface of the second bank layer, and a third bank layer below the second bank layer and comprising a second tip protruding toward the emission area from a side surface of the second bank layer;
forming an emissive layer and a cathode electrode above the anode electrode and the second pixel-defining layer;
forming a first encapsulation layer above the cathode electrode; and
removing the emissive layer, the cathode electrode, and the first encapsulation layer above the second pixel-defining layer, leaving portions of the emissive layer, the cathode electrode, and the first encapsulation layer at the emission area and at a periphery of the emission area.
